(19) United States
(12) Patent Application Publication
(10) Pub. No.: US 2018/0190614 A1
(43) Pub. Date: Jul. 5, 2018

(54) Massively parallel transfer of microLED devices

(71) Applicants: Ananda H. Kumar, Fremont, CA (US); Srinivas H. Kumar, Fremont, CA (US); Tue Nguyen, Fremont, CA (US)

(72) Inventors: Ananda H. Kumar, Fremont, CA (US); Srinivas H. Kumar, Fremont, CA (US); Tue Nguyen, Fremont, CA (US)

(21) Appl. No.: 15/831,433

(22) Filed: Dec. 5, 2017

Related U.S. Application Data
(60) Provisional application No. 62/429,877, filed on Dec. 5, 2016.

(51) Int. Cl. H01L 23/00; H01L 33/62; H01L 25/075

(52) U.S. Cl. CPC H01L 24/83; H01L 2924/12041; H01L 25/0753; H01L 24/32; H01L 2933/0066; H01L 2224/83005; H01L 2224/32013; H01L 2224/32053; H01L 2224/3207; H01L 2224/32105; H01L 2224/32111; H01L 2224/32145; H01L 2224/32227; H01L 2224/83815; H01L 2224/83143; H01L 2224/83345; H01L 2224/83385; H01L 2224/8393; H01L 33/62

(57) ABSTRACT

MicroLED devices can be transferred in large numbers to form microLED displays using processes such as pick-and-place, thermal adhesion transfer, or fluidic transfer. A blanket solder layer can be applied to connect the bond pads of the microLED devices to the terminal pads of a support substrate. After heating, the solder layer can connect the bond pads with the terminal pads in vicinity of each other. The heated solder layer can correct misalignments of the microLED devices due to the transfer process.

The present application claims priority from the provisional application Ser. No. 62/429,877, filed on Dec. 5, 2016, which is hereby incorporated by reference in its entirety.

MicroLED displays include multiple microLED devices assembled on a substrate having an interconnection networks for connecting bond pads of the microLED devices, e.g., to allow driver circuits to drive the microLED devices as individual pixels of the microLED displays.

MicroLED devices are small, e.g., about 100 microns across. The assemblies for microLED displays require large numbers of the microLED devices in close-packed arrays.

MicroLED displays can have large advantages, including low power consumption and high brightness. However, the requirement for transfer and assembly (including terminal soldering and device alignments) is still regarded after many years as a serious technological challenge blocking the commercial adoption of MicroLED displays.

### SUMMARY OF THE DESCRIPTION

In some embodiments, the present invention discloses methods to form microLED displays using a massively assembling process for connecting microLED devices onto a circuit substrate. The microLED devices can be transferred in large numbers to form microLED displays using processes such as pick-and-place, thermal adhesion transfer, or fluidic transfer. A blanket solder layer can be applied to connect the bond pads of the microLED devices to the terminal pads of a support substrate. After heating, the solder layer can connect the bond pads with the terminal pads in vicinity of each other. The heated solder layer can correct misalignments of the microLED devices due to the transfer process.

### BRIEF DESCRIPTION OF THE DRAWINGS

FIGS. 1A-1B illustrate a process for connecting and aligning bond pads according to some embodiments.

FIGS. 2A-2B illustrate a process for connecting and aligning bond pads according to some embodiments.

FIGS. 3A-3C illustrate flow charts for connecting and aligning bond pads according to some embodiments.

FIGS. 4A-4B illustrate a process for connecting and aligning bond pads of a device according to some embodiments.

FIGS. 5A-5B illustrate a process for connecting and aligning bond pads of a device according to some embodiments.

FIGS. 6A-6B illustrate a process for connecting and aligning bond pads of a device according to some embodiments.

FIGS. 7A-7B illustrate a process for connecting and aligning bond pads of a device according to some embodiments.

FIGS. 8A-8B illustrate flow charts for connecting and aligning bond pads of devices according to some embodiments.

FIGS. 9A-9B illustrate a process for connecting and aligning bond pads of a device according to some embodiments.

FIGS. 10A-10B illustrate a process for connecting and aligning bond pads of a device according to some embodiments.

FIGS. 11A-11B illustrate flow charts for connecting and aligning bond pads of devices according to some embodiments.

FIGS. 12A-12D illustrate a process for forming a microLED display according to some embodiments.

FIGS. 13A-13D illustrate a process for forming a microLED display according to some embodiments.

FIGS. 14A-14B illustrate flow charts for forming a microLED display according to some embodiments.

FIGS. 15A-15D illustrate a process for forming a microLED display according to some embodiments.

FIGS. 16A-16B illustrate flow charts for forming a microLED display according to some embodiments.

FIGS. 17A-17D illustrate a process for forming a microLED display according to some embodiments.

FIGS. 18A-18B illustrate flow charts for forming a microLED display according to some embodiments.

FIGS. 19A-19D illustrate a process forming a microLED display according to some embodiments.

FIGS. 20A-20B illustrate flow charts for forming a microLED display according to some embodiments.

FIGS. 21A-21G illustrate a process for forming a microLED display according to some embodiments.

FIGS. 22A-22B illustrate flow charts for forming a microLED display according to some embodiments.

FIGS. 23A-23E illustrate a pick-and-place process for forming microLED display according to some embodiments.

FIGS. 24A-24B illustrate flow charts for forming microLED displays using a pick-and-place process according to some embodiments.

FIGS. 25A-25D illustrate a releasable transfer process for forming microLED display according to some embodiments.

FIGS. 26A-26D illustrate a releasable transfer process for forming microLED display according to some embodiments.

FIGS. 27A-27B illustrate flow charts for forming microLED displays using a releasable transfer process according to some embodiments.

FIGS. 28A-28D illustrate a fluidic transfer process for forming microLED display according to some embodiments.

FIGS. 29A-29B illustrate flow charts for forming microLED displays using a fluidic transfer process according to some embodiments.

### DETAILED DESCRIPTION OF THE EMBODIMENTS

In some embodiments, the present invention discloses methods, and microLED displays resulted from the methods, to form microLED displays using a self-aligned massively transferring of microLED devices onto a substrate. The microLED devices, after transferred from, for example, a microLED fabricated wafer, can be automatically aligned to their proper location on the substrate by heating a low melting, high surface tension connection layer such as a solder layer containing tin. A blanket solder layer can be formed on the substrate, covering the bond pads of the microLED devices and the terminal pads of the substrate. Using a suitable alloy for the bond pads and the terminal pads, the solder can adhere to the bond pads and the terminal pads upon heating. The heated solder can connect the bond pads and the terminal pads in close proximity, while coalesced into solder balls on the substrate in the areas away from the bond pads and the terminal pads. The heated solder can align the microLED devices into their proper locations, for example, due to its high surface tension property, e.g., correcting the misalignments of the microLED devices caused by the transferring of the microLED devices on the substrate.

The substrate can have an interconnection network, including terminal pads for bonding with the bond pads of the microLED devices. The interconnection network can include conductive interconnections between the terminal pads and other connection pads, to allow the substrate, after the assembly of the microLED devices, to function as a display panel of a microLED display, e.g., a panel with the display pixels formed by the microLED devices, and with the individual pixels drivable through driver circuits.

The microLED devices can have bond pads, e.g., each microLED device can have two bond pads for lighting the microLED device. The bond pads of the microLED devices can be fabricated on the microLED device in the wafer form prior to dicing the devices into individual microLED devices, for example, by electroless nickel coating, through selective palladium activation. Once diced, the individual microLED devices can be connected into a circuit on a suitable substrate, such as display glass or a ceramic substrate.

An overlay masks can be used for aligning the microLED devices, since the microLED devices can be required to be aligned perfectly, e.g., within a tolerance specified by the microLED display products, and since misalignments of the very small geometry of the microLED devices can be a major cause of defects.

In some embodiments, the present transferring process can assemble a large number of small microLED devices without requiring the overlay mask. The present transferring process can be simple, with a robust soldering connection of the microLED devices to the substrate. The present transferring process can make use of the inherent self-aligned properties of solders, such as tin-containing materials, when applied to the bond pads and terminal pads, driven by the high surface tension of molten solders. Details of the self-alignment process due to the surface tension of the solder as applied to wafer probes can be found in U.S. Pat. Nos. 4,442,137 and 4,501,768, hereby incorporated by reference in their entirety.

In some embodiments, the bond pads and the terminal pads can be prepared using metallurgy suitable for bonding the solder. A blanket solder layer can cover the bond pads and the terminal pads, and upon meting to form molten solder, the solder can be bonded to the bond pads and the terminal pads. A flux can optionally be used to facilitate the melting and bonding process.

When heated at a suitable temperature for the melting of the solder, self-alignment can occur to minimize the surface tension, e.g., the microLED devices on the substrate can move together due to the need to minimize surface energy for the solder. In other words, the high surface tension of the molten solder can exert a force on the bond pads, to bring the microLED devices into their aligned positions which have been designed on the substrate with respect to the terminal pads.

In some embodiments, a refractory material, such as molybdenum on a bond pad or a terminal pad, can be coated with a solderable material such as nickel, for interconnection with the solder. A blanket layer of nickel can be formed on the bond pad or terminal pad, including the surrounding insulating areas. A diffusion bonding process, e.g., a heating process, can be performed to bond the nickel with the molybdenum. Upon cooling to room temperature, nickel can be delaminated from the insulator areas and torn away from the nickel coating, and can be easily removed, for example, by ultrasonic agitation. The diffusion bonding process can promote strong adhesion of nickel with molybdenum, and can provide a matched thermal expansion coefficients between the nickel film and the ceramic insulator.

Other bonding processes can be included involving layers of two metals. The metal layer literally fused to the refractory features made of molybdenum because of its behavior in elevated temperatures. The metal can form eutectic alloys during the heating. The metal can delaminate and tear away from the ceramic insulator areas, and can be easily removed from the substrate surface.

In some embodiments, the present invention discloses a self-aligned process for microLED devices on a substrate using a selective adhesion process. The selective adhesion process can use selective metals and insulator substrate so that upon heating, the metals bonded together while falling away at the insulator areas. The process can include coating the entire substrate, without a mask, with a metal layer designed for bonding with the pads and not bonding with the insulator areas. A heat treating process is performed to selectively bond the metal layer with the pads. The heating process also simultaneously causes the metal layer to lose adhesion at the surface of the insulator areas. The loosen metal layer can be removed using a vibration process such as an ultrasonic vibration.

In some embodiments, multiple microLED devices can be transferred onto a display substrate. The microLED devices can optionally be affixed to the substrate through a flux glue. The bond pads of the microLED devices can be prepared with proper metallurgical material such as nickel.

The display substrate can be processed to form a pattern layer of a suitable metal or alloy, such as silver, gold, copper or nickel. The pattern layer can form the interconnect lines required for circuits of the microLED display. The patterning layer can be processed by depositing the metal through a suitable pattern, or by etching a blanket electroless coating through a photolithographically produced mask. The pattern layer can contain terminal pads for connecting to the bond pads of the microLED devices, together with the interconnects needed for power and ground of the display. The pattern layer can be performed on the display substrate before or after transferring the microLED devices.

A blanket layer of a solderable material, e.g., a solder containing tin, is formed on the display substrate, e.g., on the substrate insulator areas and on the terminal pads.

The composite substrate, e.g., the substrate with the pattern layer, the microLED devices, and the layer of solderable material, can be heated to a temperature slightly above the melting point of the solderable material, such as about 400 degrees Celsius for tin-containing solderable materials. The tin can begin to melt. This aligns and bonds the terminal pads of the metal circuit pattern to the nickel bond pads on the LED device.

The process can provide the soldering of the circuit lines in the pattern layer to the microLED bond pads in a self-aligned way, and in a massively parallel scale. All microLED devices receive the same treatment so that even when there are millions of these individual microLED devices, they are all be processed exactly the same.

The overcoat metal can adhere to some parts (e.g., metallurgical pads) and not to other parts (insulator areas) of the substrate. Where the solderable material is not bonded, it quickly melts into tiny balls which can fall off the substrate surface by themselves, or can be easily swept away by ultrasonic or compressed air.

In some embodiments, the display substrate can include recesses to house the microLED devices. For example, the microLED devices can all roll into the recesses in the display substrate. In some embodiments, a fluidic process can be performed, using a fluid to float the microLED devices in the thin liquid. When the fluid is drained, the microLED devices can all be placed into the recesses. The fluidic transfer process can include misalignments, e.g., the microLED devices can be off from their proper locations. The misalignments can be corrected by the self-aligned bonding process described below.

The bond pads and the terminal pads can be coated with a nickel material for selective soldering connection. A thin solder layer can coat the nickel-coated bond pads and terminal pads, together with the rest of the insulating substrate. After heating, the solder can connect the bond pads with the terminal pads while aligning the microLED devices into proper locations.

In some embodiments, with proper metallurgical selection of the pads, e.g., bond pads of the microLED devices and terminal pads of the interconnection on the display substrate, together with the substrate insulator characteristics, a blanket solderable material can, after melted and re-solidified, bonds the microLED devices with the substrate in correct orientations and locations, and at a same time, removes itself from the substrate insulator areas by balling up.

In some embodiments, the present invention discloses methods for assembling a microLED device array onto a system board (such as a display backplane). The methods can include forming individual microLED devices, for example, by attaching a wafer containing the microLED devices on a large disposable carrier such as a glass substrate or a tape. The carrier is then diced to form rectangular sub-assemblies of convenient size. The sub-assemblies can be tiled onto the corresponding terminals on the system board, and flip-chip reflow joining these sub-assemblies onto the system board, during which a solder layer melts to form strong self-aligned electrical interconnects.

In some embodiments, the methods can eliminate the need for wire bonding, save time and cost, and enable forming system boards of higher reliability and manufacturing throughput. The methods can have the advantages of flip-chip joining, which has been used for single-device attachment, to the entire backplane consisting of thousands of microLED devices.

In some embodiments, the methods can include a first step of forming the microLED devices on a device wafer complete with bond pads and solder attached to the bond pads. A microLED device can include a LED device terminated with solder balls attached to the bond pads on the LED device. The solder balls can be placed on the LED devices by evaporation, by plating, or by screen-printing.

After the microLED devices are fabricated, tested and sorted on the wafer, the wafer is diced into individual microLED devices. The microLED devices can be assembled, e.g., an assemblage can consist of 10-10,000 of these microLED devices, on a substrate such as a glass substrate, which can act as a temporary disposable carrier. In some embodiments, the attachment can include adhering the microLED devices with a suitable solder flux. The solder can include tin and/or other lead-free solders. The placement and attachment of the microLED devices onto a layer of sticky high-temperature flux can be done by a vacuum pick and place process, or by dropping them in the correct orientation through a stencil onto the sticky flux. The solder flux can have a dual purpose of enabling the sticking of the microLED devices to the glass plate and also during the subsequent chip reflow process it will act to clean the oxides from the terminals and the solder balls.

The large assemblage of microLED devices can be diced into sub-assemblies of a convenient size, each of which may include more than a hundred individual microLED devices. These sub-assemblies can be placed on the receiving carrier, a glass plate which has the circuitry for the backplane including attachment pads on the same pitch and spacing as the solder balls. The alignment in this assembly process need not be perfect, but at least more than 30% of the solder balls should align to the corresponding pads on the terminals of the backplane, because of self-alignment occurring during solder reflow.

Once the diced microLED sub-assemblies are assembled to tile the entire backplane, this backplane assembly can be sent through a reflow furnace at a heating rate consistent with standard chip joining processes with peak temperatures from 370 to 450 degrees centigrade. The solder melts and joins to the terminal pads after self-aligning to the corresponding terminals. Upon cooling to room temperature, the flux residues can be removed by a solvent. The individual glass of the subassemblies can be removed and cleaned out. The carrier glass need not be reused and can be considered as sacrificial substrate. This leaves behind a backplane with self-aligned microLED devices assembled onto the entire backplane by robust solder attachment.

The microLED display can include multiple thousands of individual microLED devices, then pick and place manufacturing can be time consuming, expensive, and error prone. The present solder reflow process can assist to correct the misalignments caused by the pick and place process, resulting in a higher reliability manufacturing process.

In some embodiments, the present methods can place thousands of microLED devices in an approximate alignment to the underlying contact pads, and then join them reliably with a self-aligned process. In some embodiments, the microLED devices can be reworked, simply by removing the individual microLED devices and then putting in new microLED devices.

In some embodiments, the present methods can bring the advantages of approximate placement of the microLED devices and then the subsequent self-alignment of solder upon reflow to correct any misalignments to form a display backplane for microLED displays.

In some embodiments, the present invention can be based on using a thin film of a solderable material, e.g., materials having low melting and high bonding strength to connection pads, such as tin, as the solder source for attaching the microLED devices onto a circuit board in a systematic and self-aligned fashion. The microLED devices can have bond pads having a refractory metal coating, such as nickel, which can join to input/output terminal pads of copper interconnects on a display substrate.

In some embodiments, the methods can include three components: a circuit board, e.g., a display substrate, can have copper interconnects with input/output terminal pads for connecting with microLED devices; an array of microLED devices with nickel bond pads; and a thin film of tin to join the circuit board and the microLED devices.

The microLED devices can have different orientations upon placed on the circuit board. The circuit board can have terminal pads on a surface, together with interconnects linking the terminal pads and also to other terminal pads for connecting to other devices.

The microLED devices can have bond pads on a surface of the microLED devices. The bond pad surface of the microLED devices can face the terminal pad surface of the circuit board. Alternatively, the back side of the microLED devices, e.g., the opposite surface of the bond pad surface, can face the terminal pad surface of the circuit board.

For the first embodiment, the microLED devices need to be oriented with their bond pads all pointing downwards, facing the terminal pads on the circuit board. When the devices are placed with the bond pads oriented downwards, they are in a flip chip attachment in approximate alignment with corresponding terminal pads of the board. The solder layer can be first placed on the circuit board, followed by the microLED devices on the solder layer with the bond pads contacting the solder layer. When the solder reflows, it will melt and coat the copper terminal pads and the nickel bond pads, simultaneously aligning them with each other, because of the surface tension of the solder.

In the second embodiment, the microLED devices can be oriented with their bond pads pointed upwards. The solder layer can be provided after the microLED devices are placed on the circuit board. Once the microLED devices are properly positioned with this upward orientation, the thin film of solder is formed on the circuit board. When the solder is melted, it can reach up to the nickel bond pads to complete the interconnection between the bond pads and the terminal pads.

In both cases, the solder wets the circuits and also de-wets from the bare areas of the circuit board (where there are no contact pads) which can easily be removed. For example, the excess solder can balls up and can be removed with air, water or ultrasound.

In some embodiments, the methods uses wave soldering process with a thin film of solder instead of a solder bath. The technique of Wave Soldering uses a molten solder bath. A circuit board is passed, upside down, on top of the molten solder, so that the copper circuits on the surface of the circuit board can contact the molten solder bath. The solder can adhere to the copper circuits, and does not adhere to the areas without the copper. The circuit board can be copper circuits in close proximity can be joined by the solder.

In some embodiments, the present method uses a thin layer of solder deposited on the circuit board. Upon heating, the thin solder layer can melt and adhere to the copper or nickel pads, joining the pads that are in close proximity. The present thin solder layer can be suitable for microLED display fabrication since the microLED devices are loosely coupled to the circuit board. The conventional wave soldering of using the solder bath can be not suitable for microLED display manufacturing since microLED devices can fall from the circuit board, because the circuit board is oriented upside down.

In the present thin layer wave soldering process, the melted solder layer can coat the exposed copper circuit features previously formed on the circuit board, e.g., the terminal pads. The melted solder layer can also serve to bridge the open connections between the bond pads of the microLED devices and the terminal pads on the circuit board. The process is robust and occurs simultaneously at every single bond pad/terminal pad connection in a perfectly uniform manner, because the depth of the molten solder is uniform and controlled, making the operation inherently suited for massively parallel joining of the microLED devices onto the display wiring circuit. Furthermore, in that process, the surface tension of the solder material can cause these microLED devices to self-align, e.g., to correct the misalignments due to the placing of the microLED devices on the circuit board.

The present methods can form microLED displays using massively parallel joining of microLED devices to an interconnect substrate.

In some embodiments, the solder layer can be deposited as a thin-film on the substrate, such as by the technique of sputtering and evaporation. Alternatively, the solder layer can also be formed by screen-printing solder paste and reflow, or even by decal-transfer of a thin layer of solder.

In some embodiments, the methods can include forming bond pads each microLED device on the LED wafer before dicing, for example, by electroless nickel coating, through selective palladium activation. The methods can include blanket coating (everywhere, with no discrimination) of tin solder on the entire substrate. The tin solder thickness can be controlled be thin so as not to consume the circuit metal in the following process. The methods can include forming interconnect circuitry on the blanket-tin layer using nickel, gold, silver or copper, such as by thick-film through-metal-mask screen printing (a method in which the screen defines the pattern where the metal goes, with the metal evaporated or sputtered through the screen), or lithography. The methods can include heating the substrate at slightly above the melting point of tin so that the tin melts. Locally, the tin bonds with the circuit features, bonding them to the terminals of the LED. Where the tin melts on the insulator (of glass or ceramic), the tin de-wets and forms tiny balls which can easily be blown away with air, water or ultrasound. This process can be conducted over large areas, e.g., areas suitable for displays.

In some embodiments, the large arrays of microLED devices can be placed on the substrate (which may be display glass), through a laser-produced poly-image mask, and aligned onto it by locating pins at the edge which serve as registration marks, also holding the mask in place. Through this, the microLED devices are placed onto the substrate, and held there by a temporary flux, which acts as a glue. The flux is required because when the tin melts it may oxidize. This flux therefore serves a dual purpose of fixing the microLED devices in place as well as preventing tin oxidation during soldering.

In some embodiments, the methods can include placing microLED devices on a temporary substrate, with their contact pads (made of copper) oriented upwards from the substrate. A blanket film of solder, such as tin, can be deposited evenly on the microLED devices, covering the contact pads and any other features. The temporary substrate can be diced into equal chips of a convenient size. The diced chips can be placed on the permanent substrate, with the tin side down, in approximate alignment with the corresponding pads on the permanent substrate. No lithography is needed for approximate alignment. The assembly can be heated to about 400 degrees C. in order to melt the tin. As the tin melts, the copper contact pads on the temporary substrate and the corresponding pads on the permanent substrate join and align themselves because of surface tension alone. No other force is needed for this alignment; indeed, other forces will frustrate this self-alignment. The process involving temporary substrates can be repeated, to include as many microLED devices as are needed to form the full display, and each will join in a self-aligned fashion. Once joined, the temporary substrate must now be removed by some appropriate method. One way to remove the substrate is its dissolution with acid. In the case of a glass substrate, simple breaking, e.g., performed with a laser, can be adequate. In some embodiments, the microLED devices can use glass as the temporary substrate. Now the large array re-forms as before, because these pads in the original large array are lithographically aligned in the temporary substrate and the permanent substrate. Thus, the lithography arrangement is re-created.

In some embodiments, the process can include forming an initial substrate with copper circuit, for example, by a lithographic process. The microLED devices can be placed on the substrate, with the bond pads of the microLED devices coated with a nickel layer. A layer of solder, e.g., tin, can be overlaid over the entire substrate, covering the microLED devices and the copper wiring. A heating process can be performed to melt the solder, which can provide a self-alignment of the microLED devices, and bridge the copper connections with solder to the nickel bond pads due to surface tension forces. The excess tin in the gaps just balls up and can be blown away easily with air or ultrasound.

The thickness of the solder can be less than 100 nm, such as less than 50 nm, less than 20 nm, or less than 10 nm.

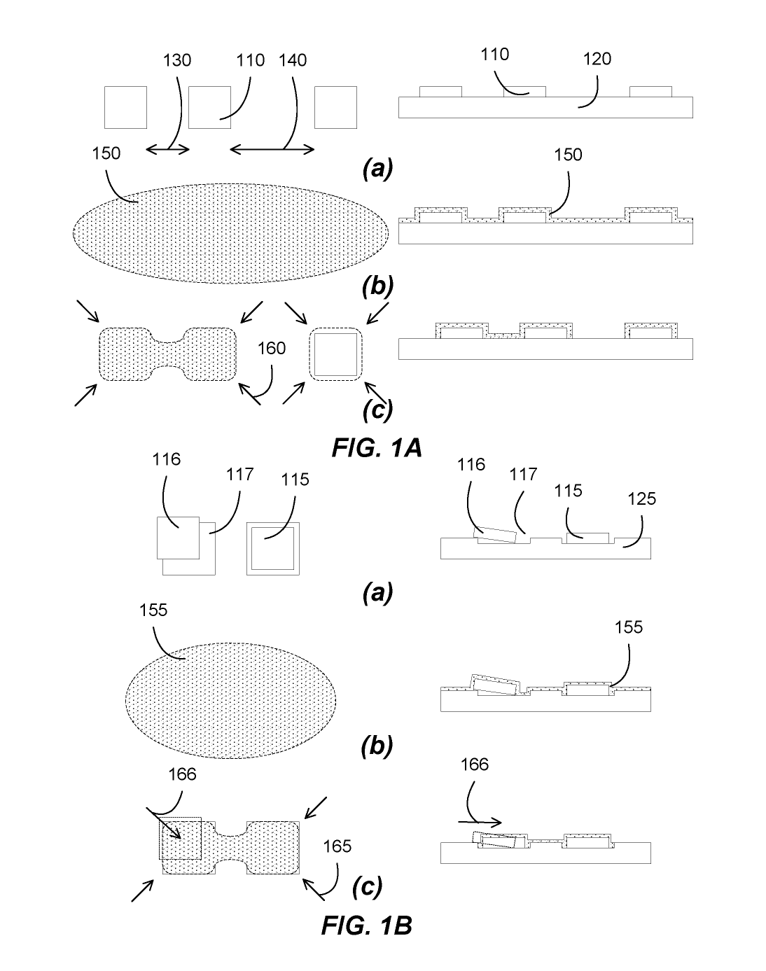

FIGS. 1A-1B illustrate a process for connecting and aligning bond pads according to some embodiments. The solder layer can be disposed on the contact pads on the substrate. In FIGS. 1A (a)-1A (c), contact pads 110 can be placed on a substrate 120. The contact pads can be coated with a metallurgical material compatible with a solderable material, such as tin. The substrate can be an insulator substrate, which does not bond with the solderable material. The contact pads can be disposed closer 130 to each other, or can be disposed farther 140 to each other. A layer of solder 150, such as tin-containing material, can be disposed on the entire substrate, e.g., over the contact pads 110 and over the surface of the substrate 120 not covered by the contact pads. The solder layer can be formed by a deposition process, such as evaporation or sputtering, or by a screen printing process of spreading a solder paste.

Upon heating, the solderable material 150 can be melted and bonded with the contact pads. The surface tension of the solderable material can bring 160 the solderable material closer to the contact pads. For contact pads in close proximity, e.g., contact pads closer 130 to each other, the solderable material can form a bridge to connect the two contact pads. For contact pads farther apart, e.g., contact pads farther away 140 from each other, the solderable material breaks off, e.g., not connecting the far apart contact pads. The solderable material away from the contact pads can be balled up, e.g., not bonded with the substrate, and can be easily removed.

This is a bonding characteristic of the solderable material, discovered by the present invention for forming connections in microLED display fabrication processes.

In FIGS. 1B (a)-1B (c), contact pads 115 and 116 can be placed in recesses 117 on a substrate 125. The contact pads can be coated with a metallurgical material compatible with a solderable material, such as tin. The substrate can be an insulator substrate, which does not bond with the solderable material. The contact pads can be misaligned, such as contact pad 116 not stayed in the recess 117.

A layer of solder 155, such as tin-containing material, can be disposed on the entire substrate, e.g., over the contact pads 115 and 116 and over the surface of the substrate 125 not covered by the contact pads. The solder layer can be formed by a deposition process, such as evaporation or sputtering, or by a screen printing process of spreading a solder paste.

Upon heating, the solderable material 155 can be melted and bonded with the contact pads. The surface tension of the solderable material can bring 165 the solderable material closer to the contact pads. The surface tension can bring 166 the contact pad 116 into position, e.g., to the recess 117. In other words, the surface tension of the reflow solderable material can correct the misalignments of the contact pads 116.

This is a self-aligned characteristic of the solderable material, discovered by the present invention for forming connections in microLED display fabrication processes.

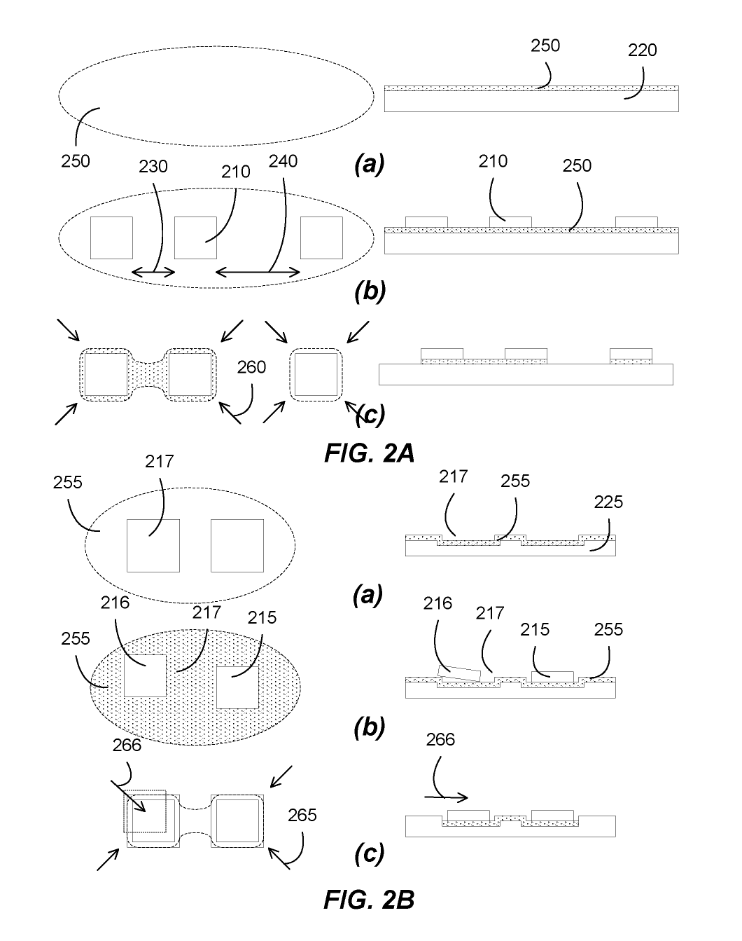

FIGS. 2A-2B illustrate a process for connecting and aligning bond pads according to some embodiments. The contact pads can be disposed on the solder layer on the substrate. In FIGS. 2A (a)-2A (c), a layer of solder 250, such as tin-containing material, can be disposed on a substrate 220. The solder layer can be formed by a deposition process, such as evaporation or sputtering, or by a screen printing process of spreading a solder paste. Contact pads 210 can be placed on the solder layer 250 on the substrate 220. The surfaces of the contact pads that contact the solder layer can be coated with a metallurgical material compatible with a solderable material, such as tin. The substrate can be an insulator substrate, which does not bond with the solderable material. The contact pads can be disposed closer 230 to each other, or can be disposed farther 240 to each other.

Upon heating, the solderable material 250 can be melted and bonded with the contact pads. The surface tension of the solderable material can bring 260 the solderable material closer to the contact pads. For contact pads in close proximity, e.g., contact pads closer 230 to each other, the solderable material can form a bridge to connect the two contact pads. For contact pads farther apart, e.g., contact pads farther away 240 from each other, the solderable material breaks off, e.g., not connecting the far apart contact pads. The solderable material away from the contact pads can be balled up, e.g., not bonded with the substrate, and can be easily removed.

In FIGS. 2B (a)-2B (c), a layer of solder 255, such as tin-containing material, can be disposed on a substrate 225 having recesses 217. The solder layer can be formed by a deposition process, such as evaporation or sputtering, or by a screen printing process of spreading a solder paste. Contact pads 215 and 216 can be placed on the solder layer 255 in the recesses 217 on a substrate 225. The surfaces of the contact pads that contact the solder layer can be coated with a metallurgical material compatible with a solderable material, such as tin. The substrate can be an insulator substrate, which does not bond with the solderable material. The contact pads can be misaligned, such as contact pad 216 not stayed in the recess 217.

Upon heating, the solderable material 255 can be melted and bonded with the contact pads. The surface tension of the solderable material can bring 265 the solderable material closer to the contact pads. The surface tension can bring 266 the contact pad 216 into position, e.g., to the recess 217. In other words, the surface tension of the reflow solderable material can correct the misalignments of the contact pads 216.

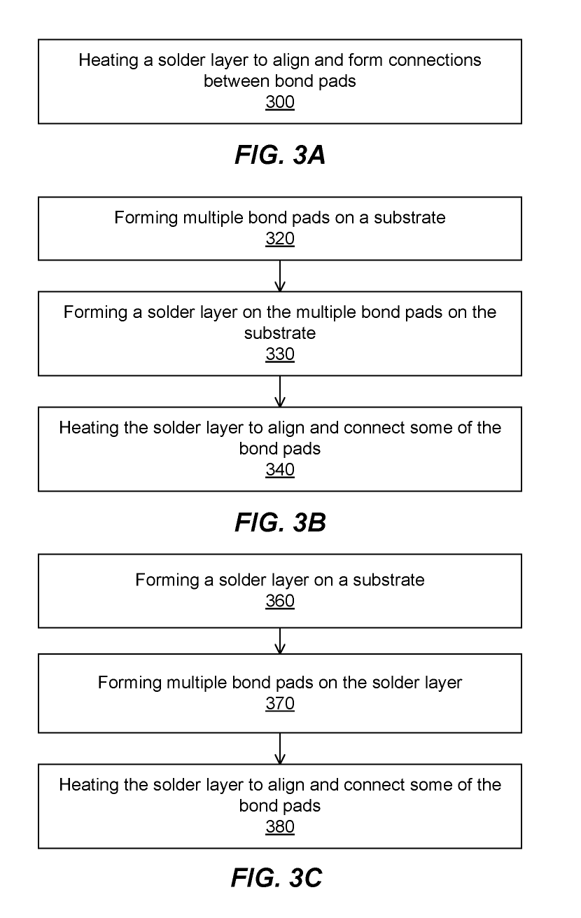

FIGS. 3A-3C illustrate flow charts for connecting and aligning bond pads according to some embodiments. In FIG. 3A, operation 300 heats a solder layer to align and form connections between bond pads. The alignment and the connection forming characteristics can be due to the surface tension of the solder layer upon heated to above a melting temperature.

In FIG. 3B, operation 320 forms multiple bond pads on a substrate. Operation 330 forms a solder layer on the multiple bond pads on the substrate. Operation 340 heats the solder layer to align and connect some of the bond pads.

In FIG. 3C, operation 360 forms a solder layer on a substrate. Operation 370 forms multiple bond pads on the solder layer. Operation 380 heats the solder layer to align and connect some of the bond pads.

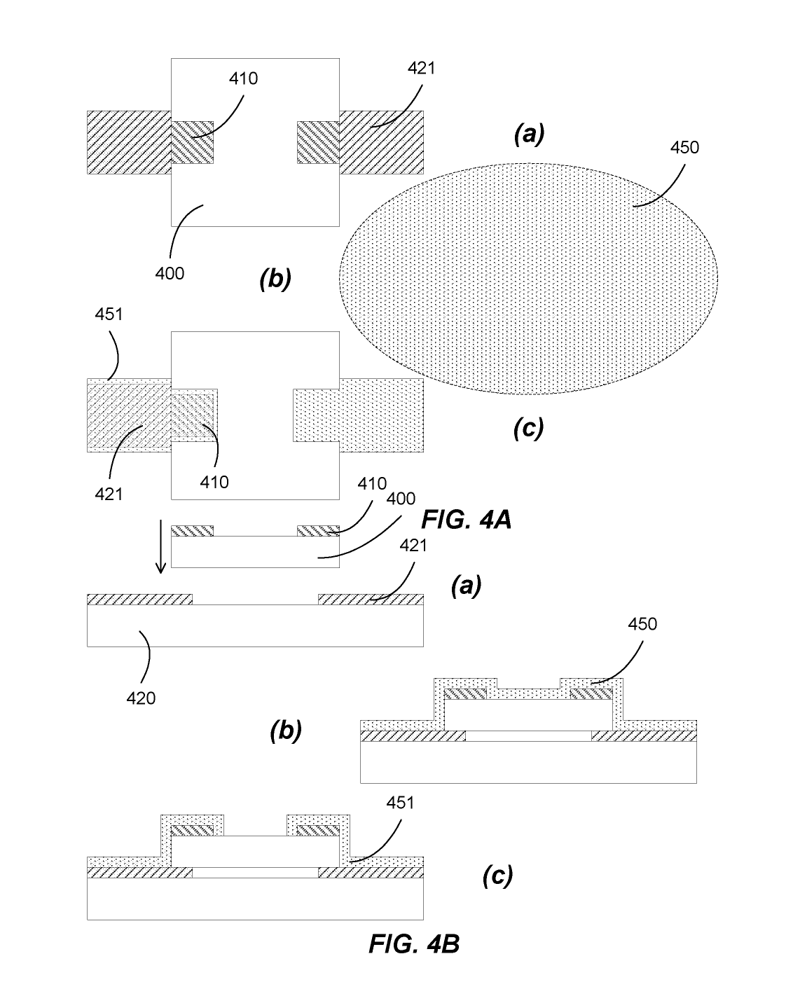

FIGS. 4A-4B illustrate a process for connecting and aligning bond pads of a device according to some embodiments. FIGS. 4A (a)-4A (c) show top views and FIGS. 4B (a)-4B (c) show cross section views for the connecting characteristic of a solder layer.

A substrate 420 can have terminal pads 421 on a top surface. The terminal pads can be formed by depositing a copper material through a shadow mask, thus generating an image of the shadow mask on the substrate. The terminal pads can be also formed by depositing a blanket copper layer, followed by a photolithography process to define a circuit pattern, followed by an etch process to transfer the circuit pattern onto the copper layer, e.g., forming the circuit pattern with the copper.

A device 400 having bond pads 410 can be placed on the substrate, configured so that the bond pads 410 are in close proximity with the terminal pads 421. The bond pads can be coated with nickel. The device can be oriented upward, e.g., the back side surface, e.g., the surface opposite the surface having the bond pads, can face the top surface of the substrate, e.g., facing the surface of the substrate having the terminal pads. The device can be positioned to overlap the terminal pads, e.g., the device can be placed on a portion of the terminal pads. For example, the device can be positioned so that the bond pads are directly over the terminal pads. As shown, the bond pads can overlap the terminal pads. Other configurations can be used, such as the terminal pads are disposed away from the bond pads.

A solder layer 450 can be formed, e.g., deposited by a deposition process or by screen printing, on the device and on the substrate. The solder layer can cover the bond pads and the terminal pads.

Upon heating, the solder can be melted. The surface tension of the molten solder layer can cause the portion of the solder layer on the bond pads and the terminal pads to make the connection 451 between the bond pads and the terminal pads. The portion of the solder layer away from the bond pads and the terminal pads can be balled up, e.g., losing the adhesion with the substrate, and can easily be removed.

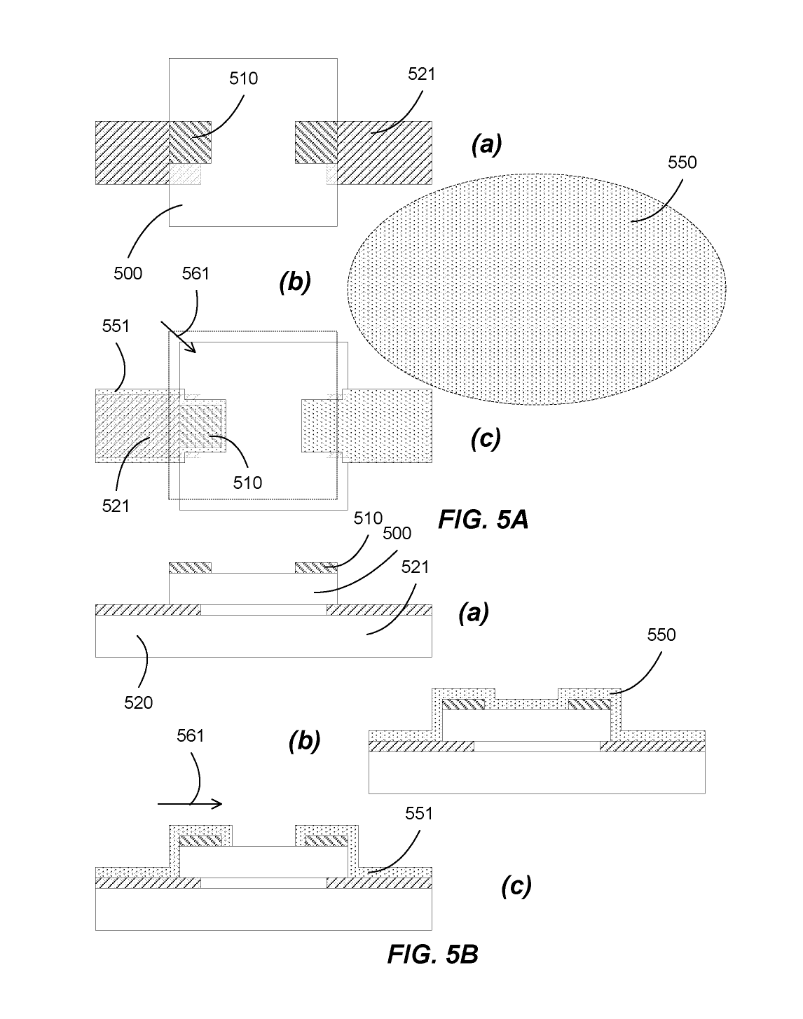

FIGS. 5A-5B illustrate a process for connecting and aligning bond pads of a device according to some embodiments. FIGS. 5A (a)-5A (c) show top views and FIGS. 5B (a)-5B (c) show cross section views for the self-alignment characteristic of a solder layer.

A substrate 520 can have terminal pads 521 on a top surface. The terminal pads can be formed by depositing a copper material through a shadow mask, thus generating an image of the shadow mask on the substrate. The terminal pads can be also formed by depositing a blanket copper layer, followed by a photolithography process to define a circuit pattern, followed by an etch process to transfer the circuit pattern onto the copper layer, e.g., forming the circuit pattern with the copper.

A device 500 having bond pads 510 can be placed on the substrate, configured so that the bond pads 510 are in close proximity with the terminal pads 521. The bond pads can be coated with nickel. The device can be oriented upward, e.g., the back side surface, e.g., the surface opposite the surface having the bond pads, can face the top surface of the substrate, e.g., facing the surface of the substrate having the terminal pads. There can be a misalignment of the device, e.g., the device can be placed to a position not designed for it.

A solder layer 550 can be formed, e.g., deposited by a deposition process or by screen printing, on the device and on the substrate. The solder layer can cover the bond pads and the terminal pads.

Upon heating, the solder can be melted. The surface tension of the molten solder layer can cause the portion of the solder layer on the bond pads and the terminal pads to make the connection 551 between the bond pads and the terminal pads. The portion of the solder layer away from the bond pads and the terminal pads can be balled up, e.g., losing the adhesion with the substrate, and can easily be removed. Further, the surface tension can correct the misalignment of the device, e.g., the molten solder can generate a force 561 acting on the device to move the device to the originally-designed position. In some embodiments, the originally-designed position of the device can be previously calculated, such as a position with a minimum, e.g., zero, force due to the surface tension of the molten solder.

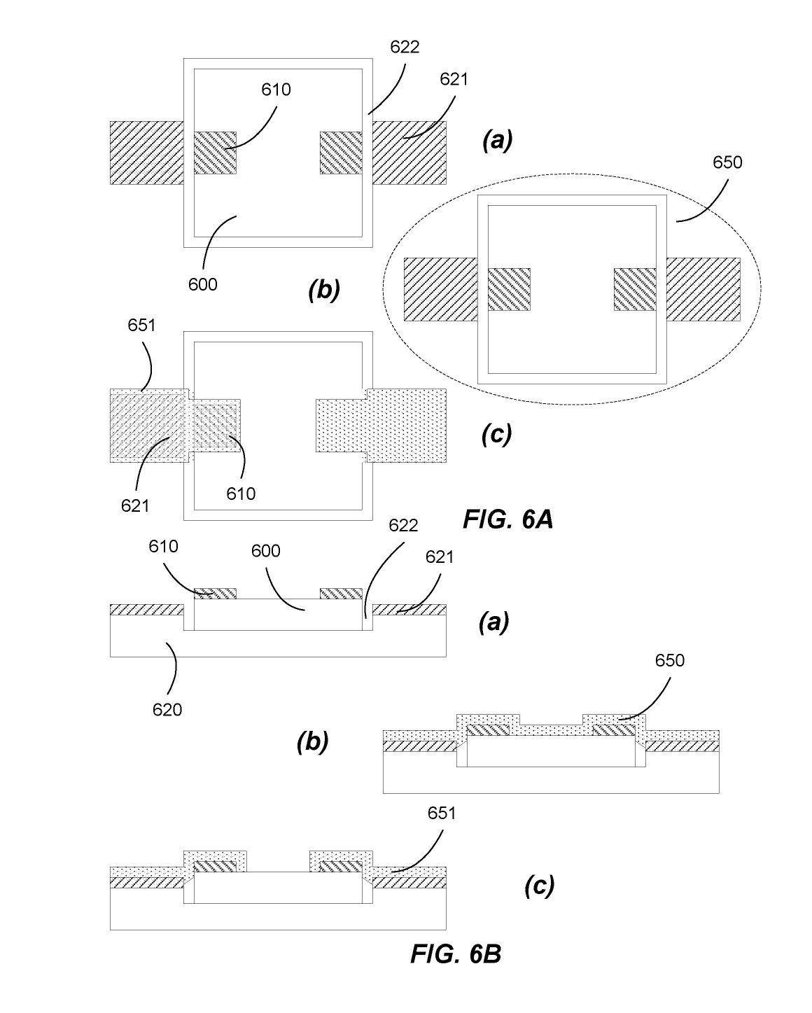

FIGS. 6A-6B illustrate a process for connecting and aligning bond pads of a device according to some embodiments. FIGS. 6A (a)-6A (c) show top views and FIGS. 6B (a)-6B (c) show cross section views for the connecting characteristic of a solder layer.

A substrate 620 can have terminal pads 621 on a top surface. The terminal pads can be formed by depositing a copper material through a shadow mask, thus generating an image of the shadow mask on the substrate. The terminal pads can be also formed by depositing a blanket copper layer, followed by a photolithography process to define a circuit pattern, followed by an etch process to transfer the circuit pattern onto the copper layer, e.g., forming the circuit pattern with the copper.

The substrate 620 can have recesses 622 for housing devices. The recesses can be indentations on the surface of the substrate. The recesses can be about the size of the devices, such as slightly larger to accommodate the devices. In some embodiments, the devices can have shapes that can determine the orientation of the devices when housed in the recesses. For example, the shape of the devices can be rectangular, which can determine a 90 degrees orientation (e.g., perpendicular to each other) due to the also-rectangular recesses. The devices can have a cut corner, which can determine a positive or negative orientation (e.g., facing to the left or to the right) due to the matched-shape recesses.

A device 600 having bond pads 610 can be placed in a recess 622 on the substrate, which is configured so that the bond pads 610 are in close proximity with the terminal pads 621. The bond pads can be coated with nickel. The device can be oriented upward, e.g., the back side surface, e.g., the surface opposite the surface having the bond pads, can face the top surface of the substrate, e.g., facing the surface of the substrate having the terminal pads. The device can be positioned so that the bond pads are in a vicinity of the terminal pads, e.g., the device can be placed between the terminal pads.

A solder layer 650 can be formed, e.g., deposited by a deposition process or by screen printing, on the device and on the substrate. The solder layer can cover the bond pads and the terminal pads.

Upon heating, the solder can be melted. The surface tension of the molten solder layer can cause the portion of the solder layer on the bond pads and the terminal pads to make the connection 651 between the bond pads and the terminal pads. The portion of the solder layer away from the bond pads and the terminal pads can be balled up, e.g., losing the adhesion with the substrate, and can easily be removed.

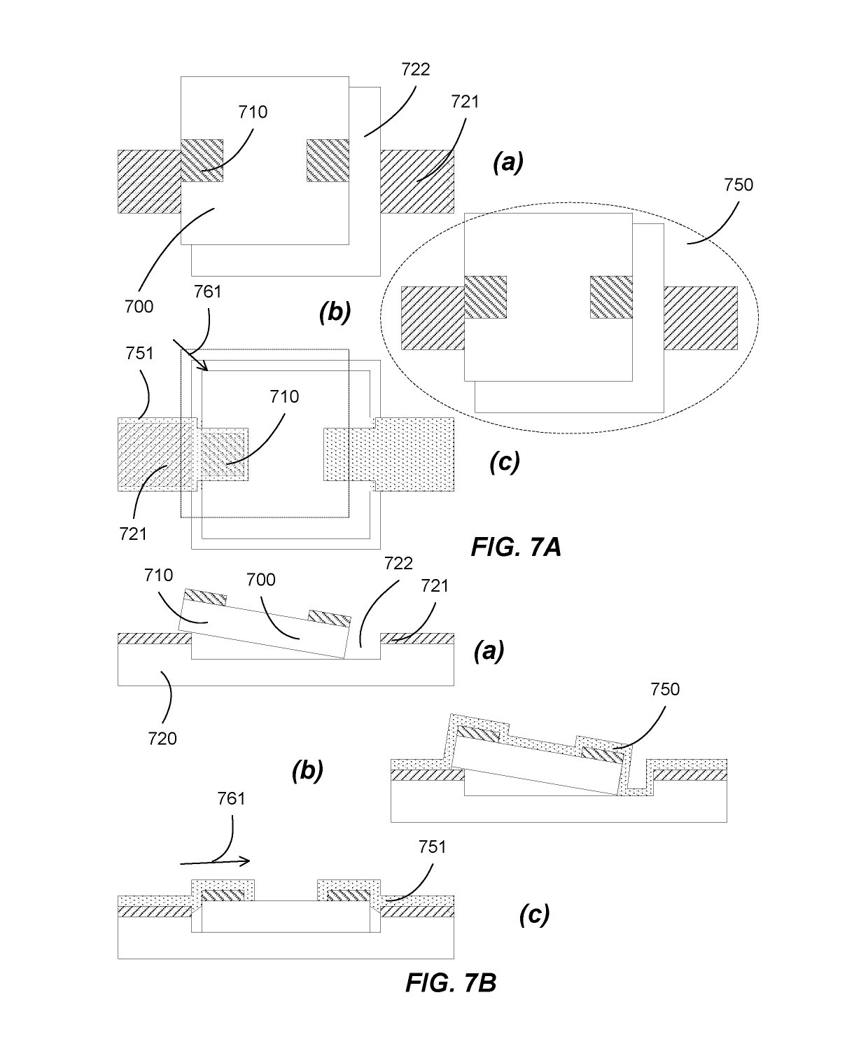

FIGS. 7A-7B illustrate a process for connecting and aligning bond pads of a device according to some embodiments. FIGS. 7A (a)-7A (c) show top views and FIGS. 7B (a)-7B (c) show cross section views for the self-alignment characteristic of a solder layer.

A substrate 720 can have terminal pads 721 on a top surface. The terminal pads can be formed by depositing a copper material through a shadow mask, thus generating an image of the shadow mask on the substrate. The terminal pads can be also formed by depositing a blanket copper layer, followed by a photolithography process to define a circuit pattern, followed by an etch process to transfer the circuit pattern onto the copper layer, e.g., forming the circuit pattern with the copper.

The substrate 720 can have recesses 722 for housing devices. The recesses can be indentations on the surface of the substrate. The recesses can be about the size of the devices, such as slightly larger to accommodate the devices. In some embodiments, the devices can have shapes that can determine the orientation of the devices when housed in the recesses. For example, the shape of the devices can be rectangular, which can determine a 90 degrees orientation (e.g., perpendicular to each other) due to the also-rectangular recesses. The devices can have a cut corner, which can determine a positive or negative orientation (e.g., facing to the left or to the right) due to the matched-shape recesses.

A device 700 having bond pads 710 can be placed in a recess 722 on the substrate, configured so that the bond pads 710 are in close proximity with the terminal pads 721. The bond pads can be coated with nickel. The device can be oriented upward, e.g., the back side surface, e.g., the surface opposite the surface having the bond pads, can face the top surface of the substrate, e.g., facing the surface of the substrate having the terminal pads. There can be a misalignment of the device, e.g., the device can be placed to a position not designed for it.

A solder layer 750 can be formed, e.g., deposited by a deposition process or by screen printing, on the device and on the substrate. The solder layer can cover the bond pads and the terminal pads.

Upon heating, the solder can be melted. The surface tension of the molten solder layer can cause the portion of the solder layer on the bond pads and the terminal pads to make the connection 751 between the bond pads and the terminal pads. The portion of the solder layer away from the bond pads and the terminal pads can be balled up, e.g., losing the adhesion with the substrate, and can easily be removed. Further, the surface tension can correct the misalignment of the device, e.g., the molten solder can generate a force 761 acting on the device to move the device to the originally-designed position. In some embodiments, the originally-designed position of the device can be previously calculated, such as a position with a minimum, e.g., zero, force due to the surface tension of the molten solder.

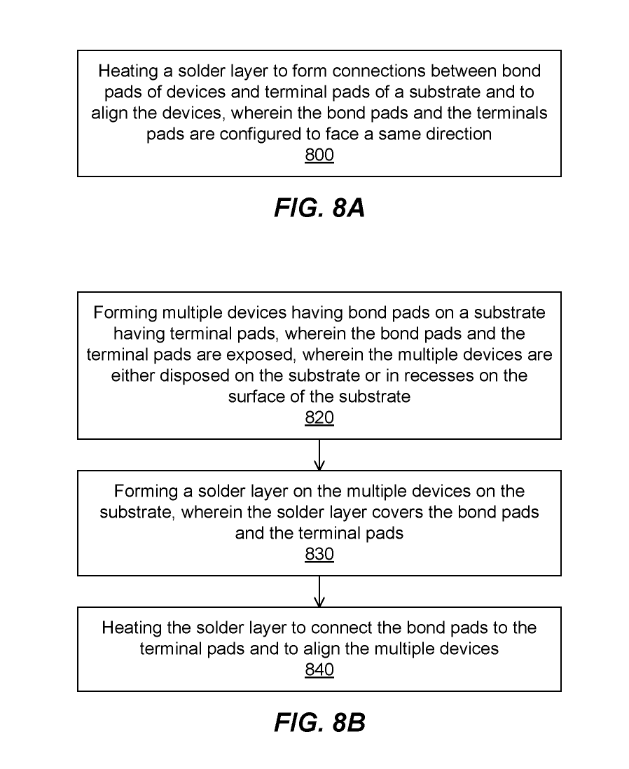

FIGS. 8A-8B illustrate flow charts for connecting and aligning bond pads of devices according to some embodiments. In FIG. 8A, operation 800 heats a solder layer to form connections between bond pads of devices and terminal pads of a substrate and to align the devices, wherein the bond pads and the terminals pads are configured to face a same direction.

In FIG. 8B, operation 820 forms multiple devices having bond pads on a substrate having terminal pads, wherein the bond pads and the terminal pads are exposed, wherein the multiple devices are either disposed on the substrate or in recesses on the surface of the substrate. Operation 830 forms a solder layer on the multiple devices on the substrate, wherein the solder layer covers the bond pads and the terminal pads. Operation 840 heats the solder layer to connect the bond pads to the terminal pads and to align the multiple devices.

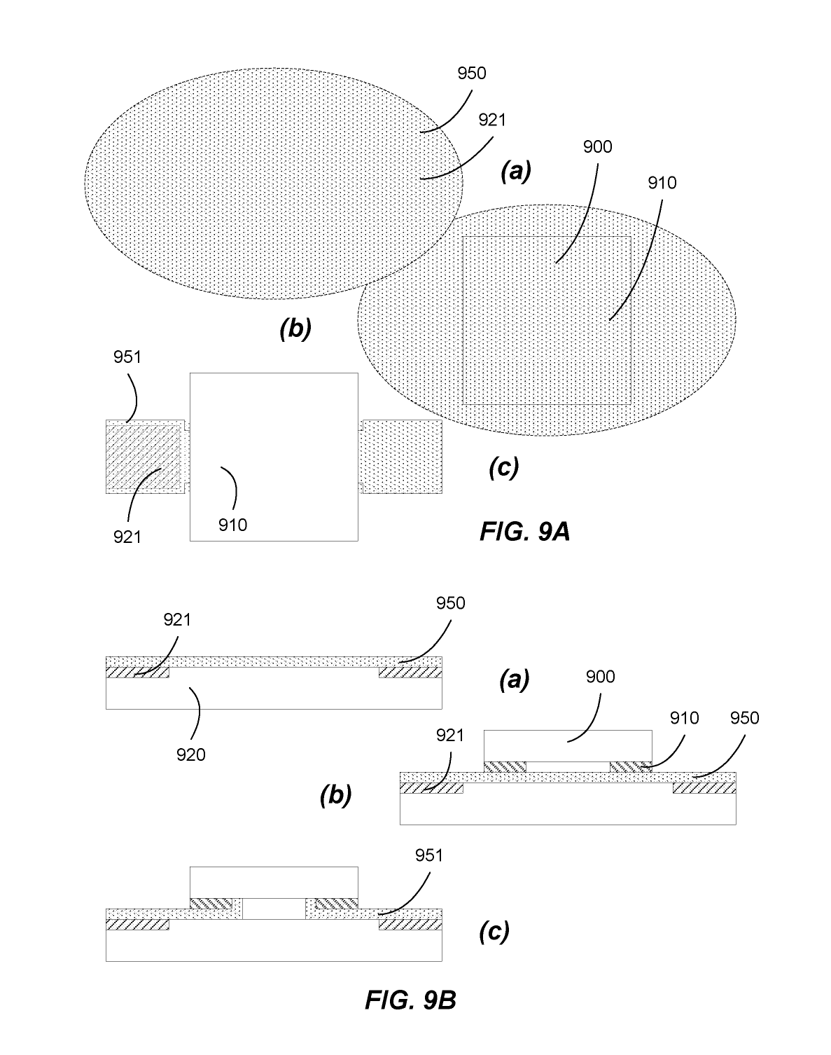

FIGS. 9A-9B illustrate a process for connecting and aligning bond pads of a device according to some embodiments. FIGS. 9A (a)-9A (c) show top views and FIGS. 9B (a)-9B (c) show cross section views for the connecting characteristic of a solder layer.

A substrate 920 can have terminal pads 921 on a top surface. The terminal pads can be formed by depositing a copper material through a shadow mask, thus generating an image of the shadow mask on the substrate. The terminal pads can be also formed by depositing a blanket copper layer, followed by a photolithography process to define a circuit pattern, followed by an etch process to transfer the circuit pattern onto the copper layer, e.g., forming the circuit pattern with the copper.

A solder layer 950 can be formed, e.g., deposited by a deposition process or by screen printing, on the substrate. The solder layer can cover the terminal pads.

A device 900 having bond pads 910 can be placed on the solder layer on the substrate, configured so that the bond pads 910 are in close proximity with the terminal pads 921. The bond pads can be coated with nickel. The device can be positioned upside down, e.g., oriented downward, or oriented so that the surface of the device having the bond pads faces the solder layer, e.g., such that the bond pads contacting the solder layer. The device can be positioned to overlap the terminal pads, e.g., the device can be placed on a portion of the terminal pads. For example, the device can be positioned so that the bond pads are directly over the terminal pads. As shown, the bond pads can overlap the terminal pads. Other configurations can be used, such as the terminal pads are disposed away from the bond pads.

Upon heating, the solder can be melted. The surface tension of the molten solder layer can cause the portion of the solder layer on the bond pads and the terminal pads to make the connection 951 between the bond pads and the terminal pads. The portion of the solder layer away from the bond pads and the terminal pads can be balled up, e.g., losing the adhesion with the substrate, and can easily be removed.

Further, the surface tension can correct any misalignment of the device, e.g., the molten solder can generate a force acting on the device to move the device to the originally-designed position. In some embodiments, the originally-designed position of the device can be previously calculated, such as a position with a minimum, e.g., zero, force due to the surface tension of the molten solder.

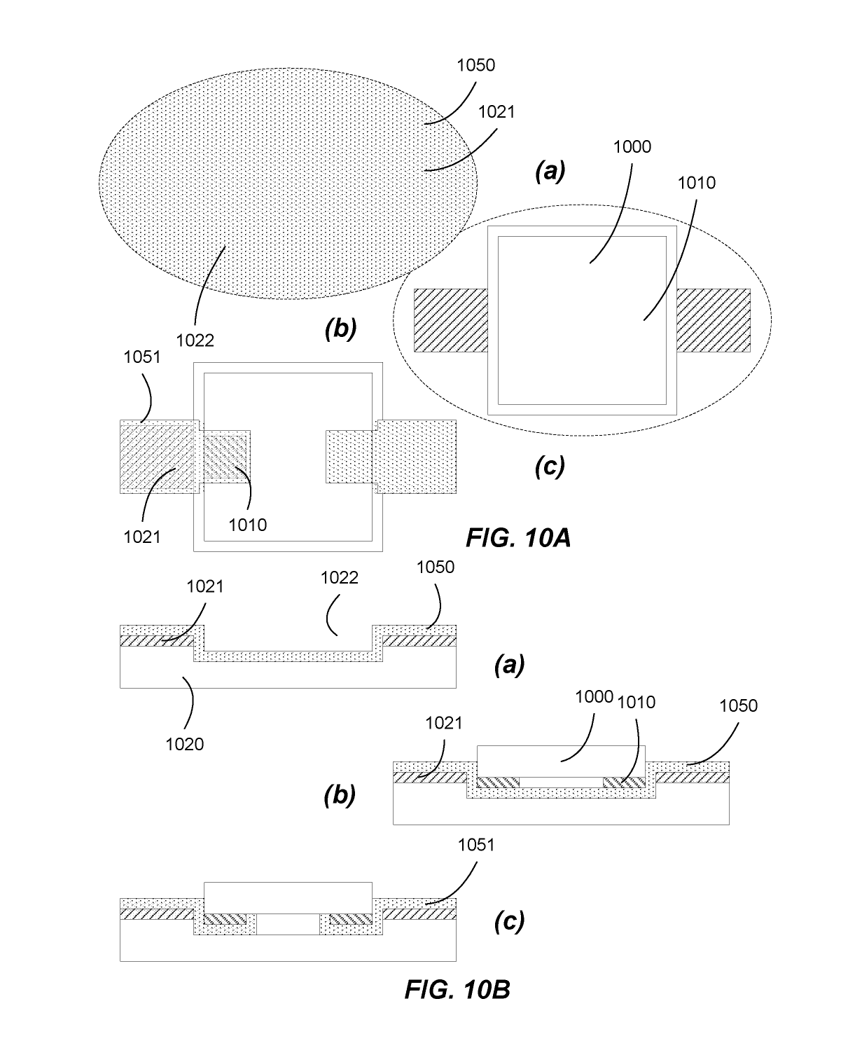

FIGS. 10A-10B illustrate a process for connecting and aligning bond pads of a device according to some embodiments. FIGS. 10A (a)-10A (c) show top views and FIGS. 10B (a)-10B (c) show cross section views for the connecting characteristic of a solder layer.

A substrate 1020 can have terminal pads 1021 on a top surface. The terminal pads can be formed by depositing a copper material through a shadow mask, thus generating an image of the shadow mask on the substrate. The terminal pads can be also formed by depositing a blanket copper layer, followed by a photolithography process to define a circuit pattern, followed by an etch process to transfer the circuit pattern onto the copper layer, e.g., forming the circuit pattern with the copper.

The substrate 1020 can have recesses 1022 for housing devices. The recesses can be indentations on the surface of the substrate. The recesses can be about the size of the devices, such as slightly larger to accommodate the devices. In some embodiments, the devices can have shapes that can determine the orientation of the devices when housed in the recesses. For example, the shape of the devices can be rectangular, which can determine a 90 degrees orientation (e.g., perpendicular to each other) due to the also-rectangular recesses. The devices can have a cut corner, which can determine a positive or negative orientation (e.g., facing to the left or to the right) due to the matched-shape recesses.

A solder layer 1050 can be formed, e.g., deposited by a deposition process or by screen printing, on the substrate and also on the recesses. The solder layer can cover the terminal pads and the recesses.

A device 1000 having bond pads 1010 can be placed in a recess 1022 on the substrate, which is configured so that the bond pads 1010 are in close proximity with the terminal pads 1021. The bond pads can be coated with nickel. The device can be positioned upside down, e.g., oriented downward, or oriented so that the surface of the device having the bond pads faces the solder layer, e.g., such that the bond pads contacting the solder layer. The device can be positioned so that the bond pads are in a vicinity of the terminal pads, e.g., the device can be placed between the terminal pads.

Upon heating, the solder can be melted. The surface tension of the molten solder layer can cause the portion of the solder layer on the bond pads and the terminal pads to make the connection 1051 between the bond pads and the terminal pads. The portion of the solder layer away from the bond pads and the terminal pads can be balled up, e.g., losing the adhesion with the substrate, and can easily be removed.

Further, the surface tension can correct the misalignment of the device, e.g., the molten solder can generate a force acting on the device to move the device to the originally-designed position. In some embodiments, the originally-designed position of the device can be previously calculated, such as a position with a minimum, e.g., zero, force due to the surface tension of the molten solder.

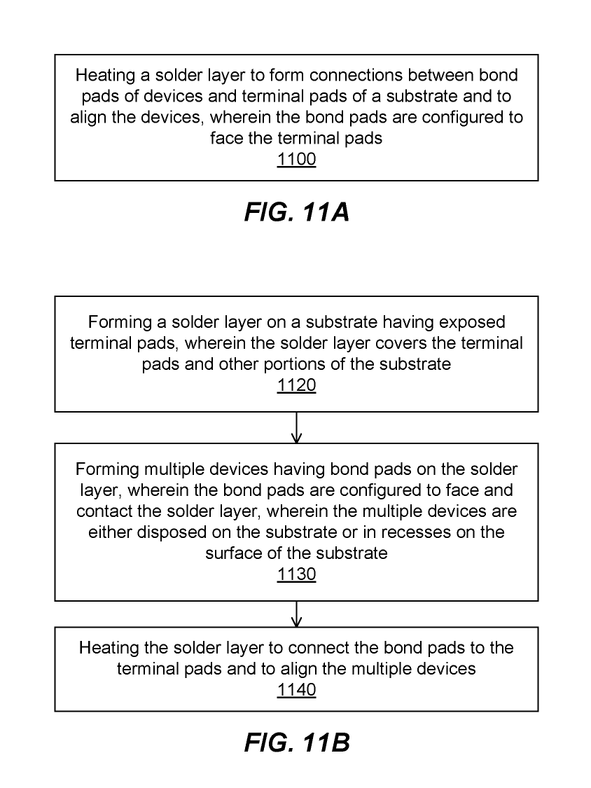

FIGS. 11A-11B illustrate flow charts for connecting and aligning bond pads of devices according to some embodiments. In FIG. 11A, operation 1100 heats a solder layer to form connections between bond pads of devices and terminal pads of a substrate and to align the devices, wherein the bond pads are configured to face the terminal pads.

In FIG. 11B, operation 1120 forms a solder layer on a substrate having exposed terminal pads, wherein the solder layer covers the terminal pads and other portions of the substrate. Operation 1130 forms multiple devices having bond pads on the solder layer, wherein the bond pads are configured to face and contact the solder layer, wherein the multiple devices are either disposed on the substrate or in recesses on the surface of the substrate. Operation 1140 heats the solder layer to connect the bond pads to the terminal pads and to align the multiple devices.

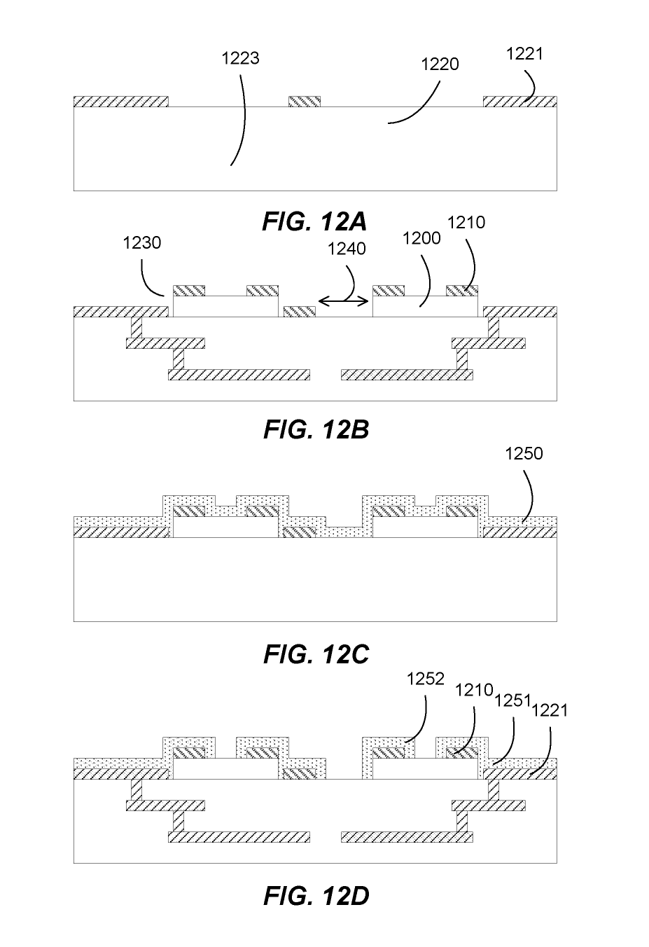

FIGS. 12A-12D illustrate a process for forming a microLED display according to some embodiments. MicroLED devices can be placed so that the bond pads of the microLED devices and terminal pads of a substrate can face upward for contacting a solder layer which is to be formed after the formation of the microLED devices on the substrate.

In FIG. 12A, a substrate 1220 can be formed. The substrate can include a circuit board. For example, the substrate can include terminal pads 1221 for coupling with bond pads of microLED devices. The substrate can include interconnects 1223 and optional circuits to drive the microLED devices, e.g., circuits and interconnections necessary for the substrate with the microLED devices to be operable as a microLED display panel. In some embodiments, the substrate can include interconnects and optional circuits necessary for the substrate with the microLED devices to be a component of a microLED display panel, e.g., the substrate can include contact pads for coupling with additional components to form a microLED display panel. For example, the substrate can include a backplane for the display. The substrate can include an insulator material, such as ceramic or glass.

In FIG. 12B, microLED devices 1200 can be placed on the substrate 1220. The microLED devices can be placed using a pick-and-place process, a thermal adhesion transfer process, a fluidic transfer process, or any other device transfer processes. The microLED devices can be oriented upward, e.g., the back side of the microLED devices (the surface opposite to the surface having the bond pads) can contact the substrate. Thus the terminal pads 1221 and the bond pads 1210 are facing upward (oriented as shown in the figure) and exposed to the ambient.

The microLED devices can be positioned so that the bond pads are located in a vicinity 1230 of the terminal pads. The distance between the bond pads and the terminal pads can be less than a maximum distance that a solderable material can bridge, e.g., the microLED devices are positioned on the substrate in such a way so that a solder layer can form a connection connecting the bond pads with the terminal pads.

The microLED devices can be positioned so that adjacent microLED devices are farther apart 1240, e.g., not in a same close proximity as the to-be-connected bond pads and terminal pads. In other words, if the microLED devices are not configured to be connected to the terminal pads, the distance between the bond pads of the non-connected microLED devices and the terminal pads can be more than the maximum distance that a solderable material can bridge, e.g., the microLED devices are positioned on the substrate in such a way so that a solder layer cannot form undesired connections between the bond pads of the non-connected microLED devices with the terminal pads.

In FIG. 12C, a layer 1250 of a solderable material, such as a tin solder material or a solder material containing tin, can be formed on the substrate, e.g., covering the microLED devices and other surface areas of the substrate. The solder layer 1250 can be configured to contact the bond pads 1210 and the terminal pads 1221.

In FIG. 12D, a heating process can be applied. For example, the entire substrate, e.g., the substrate with the microLED devices, can be placed in a furnace for annealing. The temperature of the heating process can be slightly higher than the melting of the solderable material. For example, for tin solder material, the heating temperature can be between 350 and 450 C. The molten solder can bridge the connection between the bond pads 1210 and the terminal pads 1221, e.g., forming a solder connection 1251 connecting the bond pads 1210 and the terminal pads 1221. As shown, there can be other solder connections 1252. The positions of the terminal pads and the microLED devices can be determined in advanced, e.g., can be designed, so that the solder layer can bridge the desired connections and not bridging any undesired connections, for example, through the maximum distance that the solder can bridge. The solder bridge can also correct misalignments of the microLED devices, due to the surface tension force.

Upon cooling, excess solder can be removed from the substrate, for example, by air blowing, or by ultrasonic vibration. The substrate can become a microLED display panel or a microLED backplane, e.g., a circuit board having an array of microLED display pixels. The solder layer can perform a simultaneous bridging connection for all the microLED devices, resulting in a massive parallel assembling of the microLED devices on a circuit board.

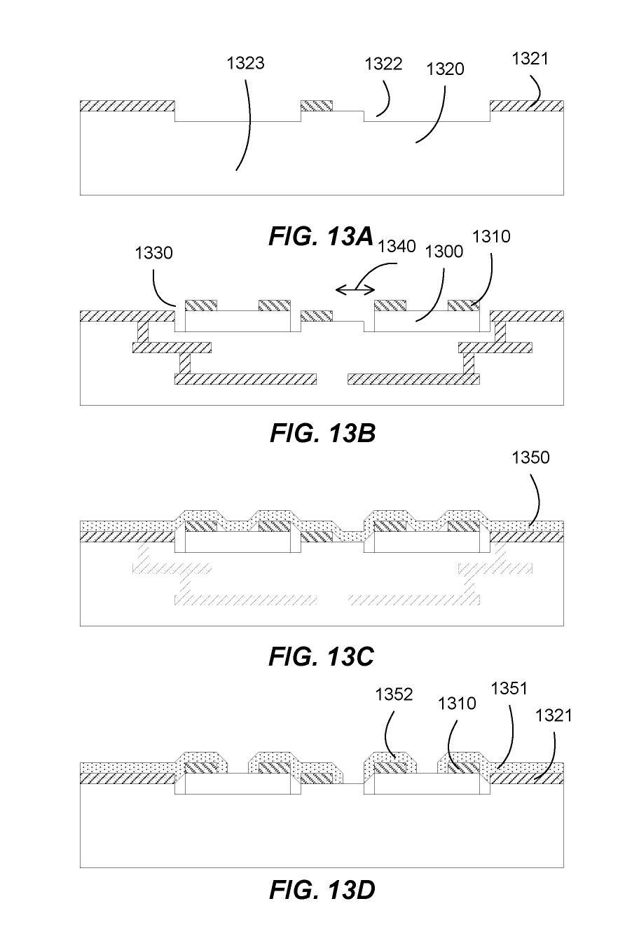

FIGS. 13A-13D illustrate a process for forming a microLED display according to some embodiments. MicroLED devices can be placed in recesses in a substrate to facilitate the transfer of the microLED devices from a microLED wafer to the substrate.

In FIG. 13A, a substrate 1320 can be formed. The substrate can include a circuit board. For example, the substrate can include terminal pads 1321 for coupling with bond pads of microLED devices. The substrate can include interconnects 1323 and optional circuits to drive the microLED devices, e.g., circuits and interconnections necessary for the substrate with the microLED devices to be operable as a microLED display panel. In some embodiments, the substrate can include interconnects and optional circuits necessary for the substrate with the microLED devices to be a component of a microLED display panel, e.g., the substrate can include contact pads for coupling with additional components to form a microLED display panel. For example, the substrate can include a backplane for the display. The substrate can include an insulator material, such as ceramic or glass.

The substrate can include recesses 1322. The recesses can be indentations on the surface of the substrate. The recesses can be about the size of the microLED devices, such as slightly larger to accommodate the microLED devices. In some embodiments, the microLED devices can have shapes that can determine the orientation of the microLED devices when housed in the recesses. For example, the shape of the microLED devices can be rectangular, which can determine a 90 degrees orientation (e.g., perpendicular to each other) due to the also-rectangular recesses. The microLED devices can have a cut corner, which can determine a positive or negative orientation (e.g., facing to the left or to the right) due to the matched-shape recesses.

In FIG. 13B, microLED devices 1300 can be placed on the substrate 1320. The microLED devices can be placed using a pick-and-place process, a thermal adhesion transfer process, a fluidic transfer process, or any other device transfer processes. The microLED devices can be oriented upward, e.g., the back side of the microLED devices (the surface opposite to the surface having the bond pads) can contact the substrate. Thus the terminal pads 1321 and the bond pads 1310 are facing upward (oriented as shown in the figure) and exposed to the ambient.

The microLED devices can be positioned so that the bond pads are located in a vicinity 1330 of the terminal pads. The distance between the bond pads and the terminal pads can be less than a maximum distance that a solderable material can bridge, e.g., the microLED devices are positioned on the substrate in such a way so that a solder layer can form a connection connecting the bond pads with the terminal pads.

The microLED devices can be positioned so that adjacent microLED devices are farther apart 1340, e.g., not in a same close proximity as the to-be-connected bond pads and terminal pads. In other words, if the microLED devices are not configured to be connected to the terminal pads, the distance between the bond pads of the non-connected microLED devices and the terminal pads can be more than the maximum distance that a solderable material can bridge, e.g., the microLED devices are positioned on the substrate in such a way so that a solder layer cannot form undesired connections between the bond pads of the non-connected microLED devices with the terminal pads.

In FIG. 13C, a layer 1350 of a solderable material, such as a tin solder material or a solder material containing tin, can be formed on the substrate, e.g., covering the microLED devices and other surface areas of the substrate. The solder layer 1350 can be configured to contact the bond pads 1310 and the terminal pads 1321.

In FIG. 13D, a heating process can be applied. For example, the entire substrate, e.g., the substrate with the microLED devices, can be placed in a furnace for annealing. The temperature of the heating process can be slightly higher than the melting of the solderable material. For example, for tin solder material, the heating temperature can be between 350 and 450 C. The molten solder can bridge the connection between the bond pads 1310 and the terminal pads 1321, e.g., forming a solder connection 1351 connecting the bond pads 1310 and the terminal pads 1321. As shown, there can be other solder connections 1352. The positions of the terminal pads and the microLED devices can be determined in advanced, e.g., can be designed, so that the solder layer can bridge the desired connections and not bridging any undesired connections, for example, through the maximum distance that the solder can bridge. The solder bridge can also correct misalignments of the microLED devices, due to the surface tension force.

Upon cooling, excess solder can be removed from the substrate, for example, by air blowing, or by ultrasonic vibration. The substrate can become a microLED display panel or a microLED backplane, e.g., a circuit board having an array of microLED display pixels. The solder layer can perform a simultaneous bridging connection for all the microLED devices, resulting in a massive parallel assembling of the microLED devices on a circuit board.

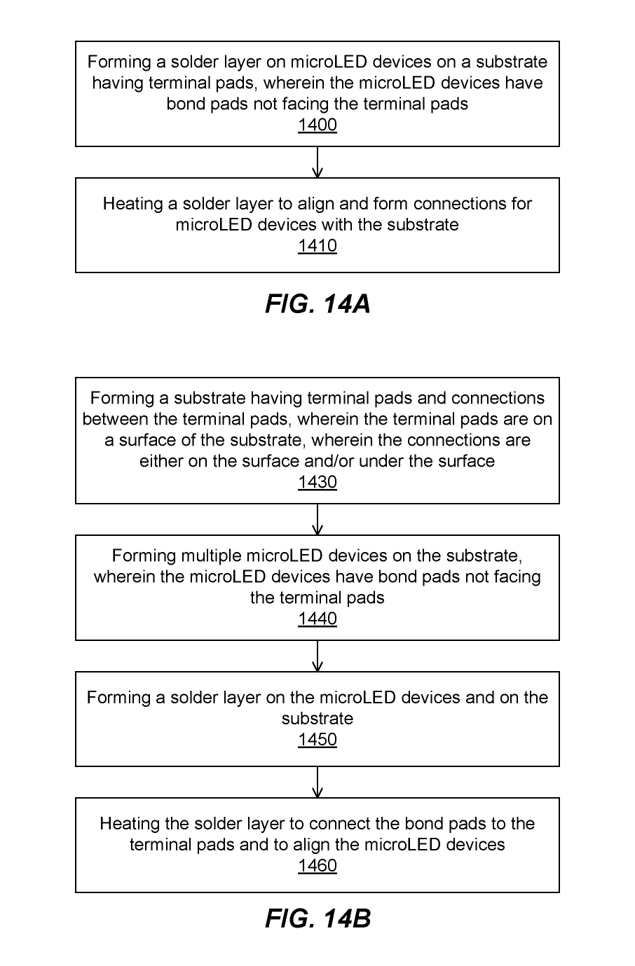

FIGS. 14A-14B illustrate flow charts for forming a microLED display according to some embodiments. In FIG. 14A, operation 1400 forms a solder layer on microLED devices on a substrate having terminal pads, wherein the microLED devices have bond pads not facing the terminal pads. Operation 1410 heats a solder layer to align and form connections for microLED devices with the substrate.

In FIG. 14B, operation 1430 forms a substrate having terminal pads and connections between the terminal pads, wherein the terminal pads are on a surface of the substrate, wherein the connections are either on the surface and/or under the surface. Operation 1440 forms multiple microLED devices on the substrate, wherein the microLED devices have bond pads not facing the terminal pads. Operation 1450 forms a solder layer on the microLED devices and on the substrate. Operation 1460 heats the solder layer to connect the bond pads to the terminal pads and to align the microLED devices.

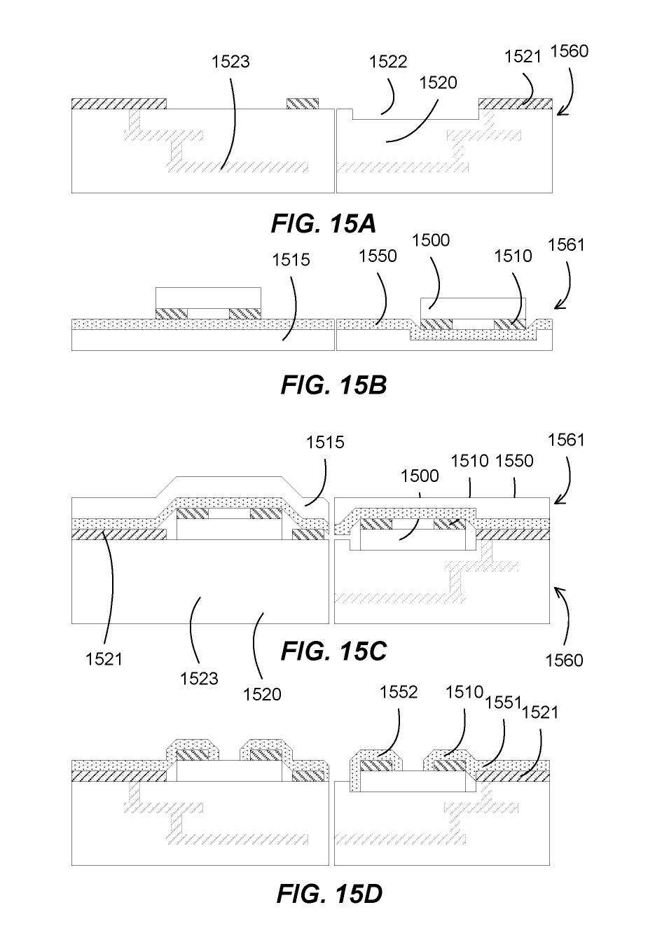

FIGS. 15A-15D illustrate a process for forming a microLED display according to some embodiments. MicroLED devices can be placed on a solder layer on a sacrificial substrate so that the bond pads of the microLED devices contact the solder layer. The sacrificial substrate can be placed on a substrate having the terminal pads, so that the solder layer also contacts the terminal pads.

In FIG. 15A, a substrate 1520 can be formed. The substrate can include a circuit board. For example, the substrate can include terminal pads 1521 for coupling with bond pads of microLED devices. The substrate can include interconnects 1523 and optional circuits to drive the microLED devices, e.g., circuits and interconnections necessary for the substrate with the microLED devices to be operable as a microLED display panel. In some embodiments, the substrate can include interconnects and optional circuits necessary for the substrate with the microLED devices to be a component of a microLED display panel, e.g., the substrate can include contact pads for coupling with additional components to form a microLED display panel. For example, the substrate can include a backplane for the display. The substrate can include an insulator material, such as ceramic or glass.

The substrate can include recesses 1522. The recesses can be indentations on the surface of the substrate. The recesses can be about the size of the microLED devices, such as slightly larger to accommodate the microLED devices. In some embodiments, the microLED devices can have shapes that can determine the orientation of the microLED devices when housed in the recesses. For example, the shape of the microLED devices can be rectangular, which can determine a 90 degrees orientation (e.g., perpendicular to each other) due to the also-rectangular recesses. The microLED devices can have a cut corner, which can determine a positive or negative orientation (e.g., facing to the left or to the right) due to the matched-shape recesses.

A first composite substrate 1560 can be formed, including the substrate 1520 with the recesses 1522 and the terminal pads 1521 and the interconnections 1523.

In FIG. 15B, a sacrificial substrate 1515 can be provided. The sacrificial substrate can be a flat substrate. The sacrificial substrate can include recesses or other features, such as protrusions to accommodate the microLED devices. A layer 1550 of a solderable material, such as a tin solder material or a solder material containing tin, can be formed on the sacrificial substrate 1515, e.g., covering the surface areas of the substrate including the surface of the optional recesses or protrusions.

MicroLED devices 1500 can be placed on the solder layer 1550 on the sacrificial substrate 1515. The microLED devices can be placed in the optional recesses or protrusions or can be placed directly on the substrate. The microLED devices can be placed using a pick-and-place process, a thermal adhesion transfer process, a fluidic transfer process, or any other device transfer processes. The microLED devices can be oriented downward, e.g., the surface of the microLED devices having the bond pads can face the solder layer and the substrate, so that the bond pads can contact the solder layer.

A second composite substrate 1561 can be formed, including the sacrificial substrate 1515 with the optional recesses or protrusions, the solder layer 1550, and the microLED devices.

In FIG. 15C, the second composite substrate 1561 can be placed on the first composite substrate 1560, e.g., the sacrificial substrate 1515 can be placed on the circuit substrate 1520. The composite substrates can be oriented so that the solder layer 1550 can be configured to contact the terminal pads 1521. Thus the terminal pads 1521 and the bond pads 1510 are facing each other with the solder layer in between.

The composite substrates can be further oriented so that the microLED devices can be positioned so that the bond pads are located in a vicinity 1530 of the terminal pads. The distance between the bond pads and the terminal pads can be less than a maximum distance that a solderable material can bridge, e.g., the microLED devices are positioned on the substrate in such a way so that a solder layer can form a connection connecting the bond pads with the terminal pads.

The microLED devices can be positioned so that adjacent microLED devices are farther apart 1540, e.g., not in a same close proximity as the to-be-connected bond pads and terminal pads. In other words, if the microLED devices are not configured to be connected to the terminal pads, the distance between the bond pads of the non-connected microLED devices and the terminal pads can be more than the maximum distance that a solderable material can bridge, e.g., the microLED devices are positioned on the substrate in such a way so that a solder layer cannot form undesired connections between the bond pads of the non-connected microLED devices with the terminal pads.

In FIG. 15D, a heating process can be applied. For example, the entire substrate, e.g., the substrate with the microLED devices, can be placed in a furnace for annealing. The temperature of the heating process can be slightly higher than the melting of the solderable material. For example, for tin solder material, the heating temperature can be between 350 and 450 C. The molten solder can bridge the connection between the bond pads 1510 and the terminal pads 1521, e.g., forming a solder connection 1551 connecting the bond pads 1510 and the terminal pads 1521. As shown, there can be other solder connections 1552. The positions of the terminal pads and the microLED devices can be determined in advanced, e.g., can be designed, so that the solder layer can bridge the desired connections and not bridging any undesired connections, for example, through the maximum distance that the solder can bridge. The solder bridge can also correct misalignments of the microLED devices, due to the surface tension force.

Upon cooling, excess solder can be removed from the substrate, for example, by air blowing, or by ultrasonic vibration. The substrate can become a microLED display panel or a microLED backplane, e.g., a circuit board having an array of microLED display pixels. The solder layer can perform a simultaneous bridging connection for all the microLED devices, resulting in a massive parallel assembling of the microLED devices on a circuit board.

The sacrificial substrate 1515 can be removed.

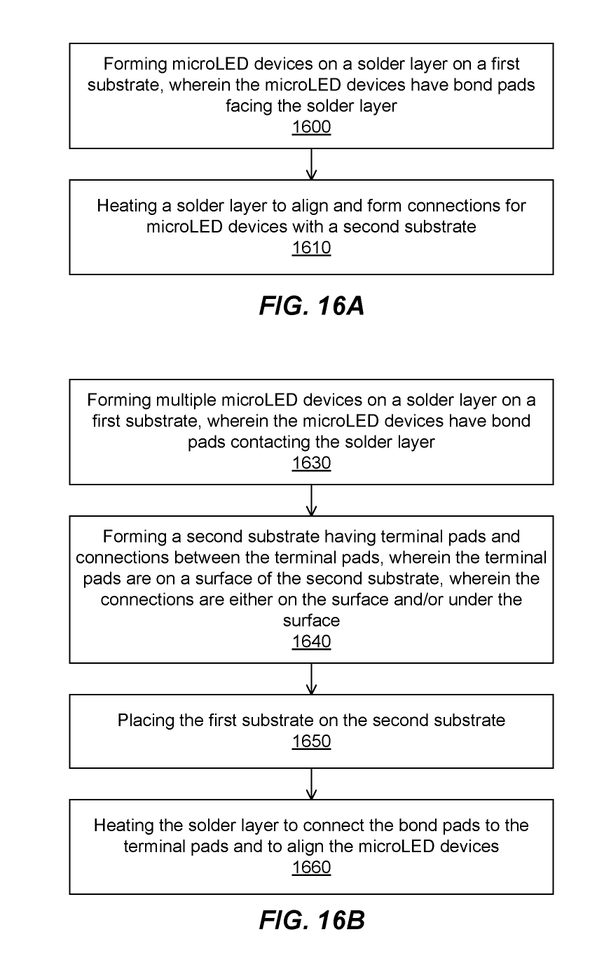

FIGS. 16A-16B illustrate flow charts for forming a microLED display according to some embodiments. In FIG. 16A, operation 1600 forms microLED devices on a solder layer on a first substrate, wherein the microLED devices have bond pads facing the solder layer. Operation 1610 heats a solder layer to align and form connections for microLED devices with a second substrate.

In FIG. 16B, operation 1630 forms multiple microLED devices on a solder layer on a first substrate, wherein the microLED devices have bond pads contacting the solder layer. Operation 1640 forms a second substrate having terminal pads and connections between the terminal pads, wherein the terminal pads are on a surface of the second substrate, wherein the connections are either on the surface and/or under the surface. Operation 1650 places the first substrate on the second substrate. Operation 1660 heats the solder layer to connect the bond pads to the terminal pads and to align the microLED devices.

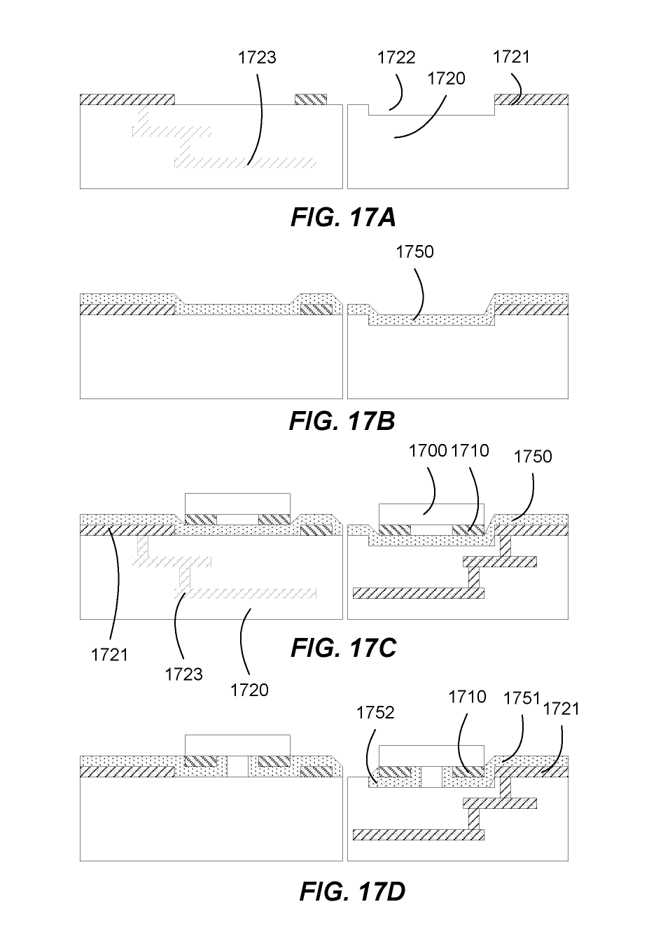

FIGS. 17A-17D illustrate a process for forming a microLED display according to some embodiments. MicroLED devices can be placed so that the bond pads of the microLED devices face the terminal pads of a substrate. The bond pads and the terminal pads can sandwich a solder layer which is to be formed before the formation of the microLED devices on the substrate.

In FIG. 17A, a substrate 1720 can be formed. The substrate can include a circuit board. For example, the substrate can include terminal pads 1721 for coupling with bond pads of microLED devices. The substrate can include interconnects 1723 and optional circuits to drive the microLED devices, e.g., circuits and interconnections necessary for the substrate with the microLED devices to be operable as a microLED display panel. In some embodiments, the substrate can include interconnects and optional circuits necessary for the substrate with the microLED devices to be a component of a microLED display panel, e.g., the substrate can include contact pads for coupling with additional components to form a microLED display panel. For example, the substrate can include a backplane for the display. The substrate can include an insulator material, such as ceramic or glass.

The substrate can include recesses 1722. The recesses can be indentations on the surface of the substrate. The recesses can be about the size of the microLED devices, such as slightly larger to accommodate the microLED devices. In some embodiments, the microLED devices can have shapes that can determine the orientation of the microLED devices when housed in the recesses. For example, the shape of the microLED devices can be rectangular, which can determine a 90 degrees orientation (e.g., perpendicular to each other) due to the also-rectangular recesses. The microLED devices can have a cut corner, which can determine a positive or negative orientation (e.g., facing to the left or to the right) due to the matched-shape recesses.

In FIG. 17B, a layer 1750 of a solderable material, such as a tin solder material or a solder material containing tin, can be formed on the substrate, e.g., covering the surface areas of the substrate including the surface of the recesses. The solder layer 1750 can be configured to contact the terminal pads 1721.

In FIG. 17C, microLED devices 1700 can be placed on the solder layer 1750 on the substrate 1720. The microLED devices can be placed in the recesses or can be placed directly on the substrate. The microLED devices can be placed using a pick-and-place process, a thermal adhesion transfer process, a fluidic transfer process, or any other device transfer processes. The microLED devices can be oriented downward, e.g., the surface of the microLED devices having the bond pads can face the solder layer and the substrate, so that the bond pads can contact the solder layer. Thus the terminal pads 1721 and the bond pads 1710 are facing each other with the solder layer in between.

The microLED devices can be positioned so that the bond pads are located in a vicinity 1730 of the terminal pads. The distance between the bond pads and the terminal pads can be less than a maximum distance that a solderable material can bridge, e.g., the microLED devices are positioned on the substrate in such a way so that a solder layer can form a connection connecting the bond pads with the terminal pads.

The microLED devices can be positioned so that adjacent microLED devices are farther apart 1740, e.g., not in a same close proximity as the to-be-connected bond pads and terminal pads. In other words, if the microLED devices are not configured to be connected to the terminal pads, the distance between the bond pads of the non-connected microLED devices and the terminal pads can be more than the maximum distance that a solderable material can bridge, e.g., the microLED devices are positioned on the substrate in such a way so that a solder layer cannot form undesired connections between the bond pads of the non-connected microLED devices with the terminal pads.

In FIG. 17D, a heating process can be applied. For example, the entire substrate, e.g., the substrate with the microLED devices, can be placed in a furnace for annealing. The temperature of the heating process can be slightly higher than the melting of the solderable material. For example, for tin solder material, the heating temperature can be between 350 and 450 C. The molten solder can bridge the connection between the bond pads 1710 and the terminal pads 1721, e.g., forming a solder connection 1751 connecting the bond pads 1710 and the terminal pads 1721. As shown, there can be other solder connections 1752. The positions of the terminal pads and the microLED devices can be determined in advanced, e.g., can be designed, so that the solder layer can bridge the desired connections and not bridging any undesired connections, for example, through the maximum distance that the solder can bridge. The solder bridge can also correct misalignments of the microLED devices, due to the surface tension force.

Upon cooling, excess solder can be removed from the substrate, for example, by air blowing, or by ultrasonic vibration. The substrate can become a microLED display panel or a microLED backplane, e.g., a circuit board having an array of microLED display pixels. The solder layer can perform a simultaneous bridging connection for all the microLED devices, resulting in a massive parallel assembling of the microLED devices on a circuit board.

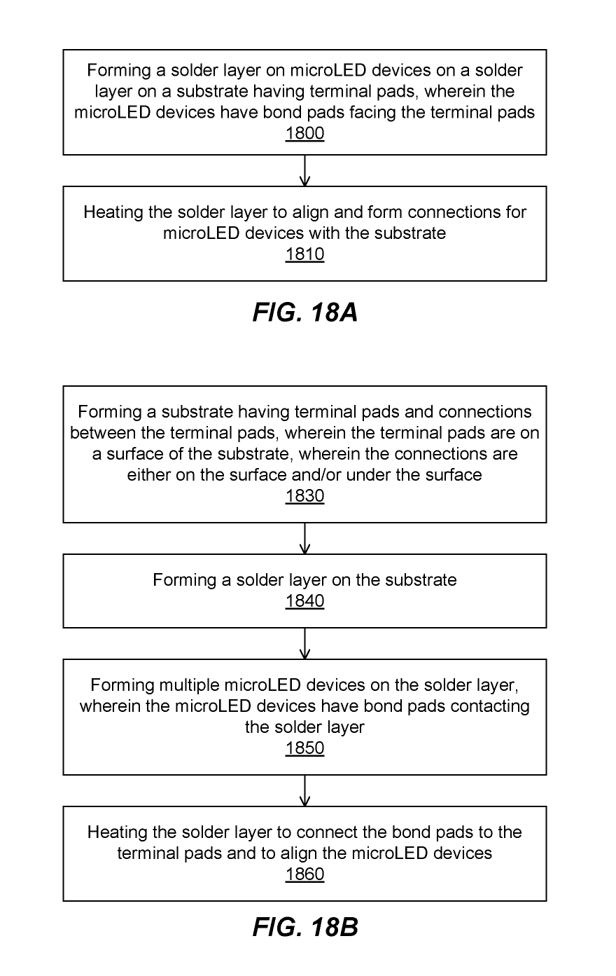

FIGS. 18A-18B illustrate flow charts for forming a microLED display according to some embodiments. In FIG. 18A, operation 1800 forms a solder layer on microLED devices on a solder layer on a substrate having terminal pads, wherein the microLED devices have bond pads facing the terminal pads. Operation 1810 heats the solder layer to align and form connections for microLED devices with the substrate.

In FIG. 18B, operation 1830 forms a substrate having terminal pads and connections between the terminal pads, wherein the terminal pads are on a surface of the substrate, wherein the connections are either on the surface and/or under the surface. Operation 1840 forms a solder layer on the substrate. Operation 1850 forms multiple microLED devices on the solder layer, wherein the microLED devices have bond pads contacting the solder layer. Operation 1860 heats the solder layer to connect the bond pads to the terminal pads and to align the microLED devices.

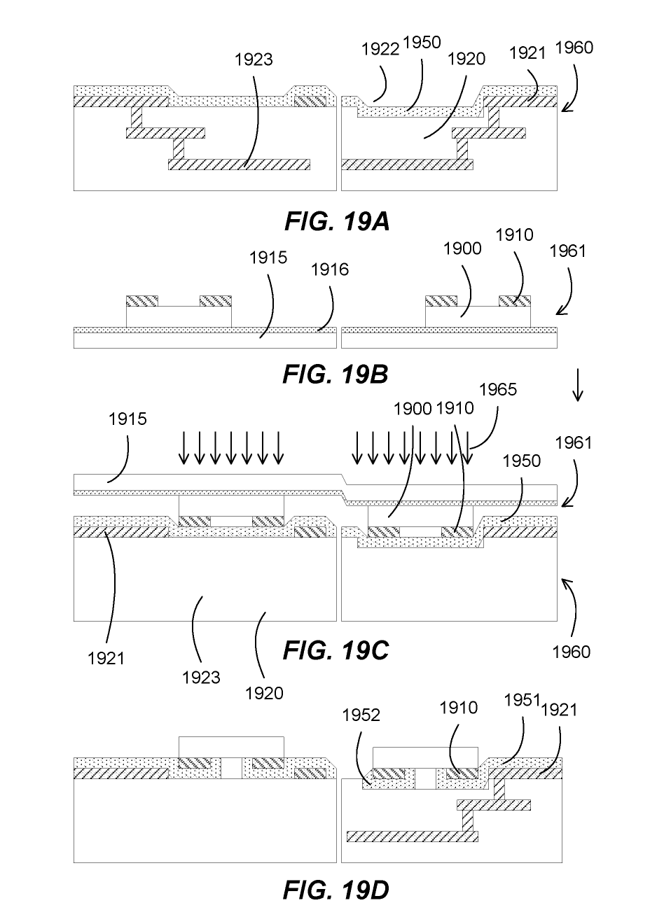

FIGS. 19A-19D illustrate a process for forming a microLED display according to some embodiments. MicroLED devices can be placed on a sacrificial substrate, e.g., on a substrate that can be removed in subsequent operations, or on a sacrificial layer on a donor substrate. The sacrificial layer can be removed, for example, by heat or light using a thermal or light released material, such as a material that sublimed upon exposing to heat and/or light.

In FIG. 19A, a substrate 1920 can be formed. The substrate can include a circuit board. For example, the substrate can include terminal pads 1921 for coupling with bond pads of microLED devices. The substrate can include interconnects 1923 and optional circuits to drive the microLED devices, e.g., circuits and interconnections necessary for the substrate with the microLED devices to be operable as a microLED display panel. In some embodiments, the substrate can include interconnects and optional circuits necessary for the substrate with the microLED devices to be a component of a microLED display panel, e.g., the substrate can include contact pads for coupling with additional components to form a microLED display panel. For example, the substrate can include a backplane for the display. The substrate can include an insulator material, such as ceramic or glass.

The substrate can optionally include recesses 1922. The recesses can be indentations on the surface of the substrate. The recesses can be about the size of the microLED devices, such as slightly larger to accommodate the microLED devices. In some embodiments, the microLED devices can have shapes that can determine the orientation of the microLED devices when housed in the recesses. For example, the shape of the microLED devices can be rectangular, which can determine a 90 degrees orientation (e.g., perpendicular to each other) due to the also-rectangular recesses. The microLED devices can have a cut corner, which can determine a positive or negative orientation (e.g., facing to the left or to the right) due to the matched-shape recesses.

A layer 1950 of a solderable material, such as a tin solder material or a solder material containing tin, can be formed on the substrate 1920, e.g., covering the surface areas of the substrate including the surface of the optional recesses or protrusions.

A first composite substrate 1960 can be formed, including the substrate 1920 with the recesses 1922 and the terminal pads 1921 and the interconnections 1923, together with the solder layer.

In FIG. 19B, a sacrificial substrate 1915 can be provided. The sacrificial substrate can be a flat substrate. The sacrificial substrate can include recesses or other features, such as protrusions to accommodate the microLED devices. A releasable layer 1916 can be coated on the sacrificial substrate. The releasable layer can include a releasable material, which can adhere to an object, such as to microLED devices, which are placed on the releasable layer. Upon certain conditions, such as in an application of heat and/or light, the releasable material can lose the adhesion, such as by evaporation or sublimation, to release the object, e.g., to transfer the microLED devices from the sacrificial substrate to a final substrate. The releasable material can include a polymer.

MicroLED devices 1900 can be placed on the releasable layer 1916 on the sacrificial substrate 1915. The microLED devices can be placed in the optional recesses or protrusions or can be placed directly on the substrate. The microLED devices can be placed using a pick-and-place process, a thermal adhesion transfer process, a fluidic transfer process, or any other device transfer processes. The microLED devices can be oriented upward, e.g., the back side of the microLED devices (the surface opposite to the surface having the bond pads) can contact the releasable layer on the sacrificial substrate. Thus the bond pads are facing upward and exposed to the ambient.

In some embodiments, the microLED devices can be placed directly on the sacrificial substrate, if the microLED devices can be easily removed from the sacrificial substrate. For example, the sacrificial substrate can contain materials that can be etched away, such as by placing the sacrificial substrate in a liquid etchant to dissolve the interface layer between the sacrificial substrate and the microLED devices.

A second composite substrate 1961 can be formed, including the sacrificial substrate 1915 with the optional recesses or protrusions, the releasable layer 1916, and the microLED devices.

In FIG. 19C, the second composite substrate 1961 can be placed on the first composite substrate 1960, e.g., the sacrificial substrate 1915 can be placed on the circuit substrate 1920. The composite substrates can be oriented so that the solder layer 1950 can be configured to contact the terminal pads 1921. Thus the terminal pads 1921 and the bond pads 1910 are facing each other with the solder layer in between.

The composite substrates can be further oriented so that the microLED devices can be positioned so that the bond pads are located in a vicinity 1930 of the terminal pads. The distance between the bond pads and the terminal pads can be less than a maximum distance that a solderable material can bridge, e.g., the microLED devices are positioned on the substrate in such a way so that a solder layer can form a connection connecting the bond pads with the terminal pads.

The microLED devices can be positioned so that adjacent microLED devices are farther apart 1940, e.g., not in a same close proximity as the to-be-connected bond pads and terminal pads. In other words, if the microLED devices are not configured to be connected to the terminal pads, the distance between the bond pads of the non-connected microLED devices and the terminal pads can be more than the maximum distance that a solderable material can bridge, e.g., the microLED devices are positioned on the substrate in such a way so that a solder layer cannot form undesired connections between the bond pads of the non-connected microLED devices with the terminal pads.

A releasable process can be performed to release the microLED devices from the sacrificial substrate. For example, a blanket exposure of the sacrificial substrate of a heat source and/or a light source can dissolve the releasable layer, separating the microLED devices from the sacrificial substrate. Alternatively, a selected application 1965 of a heat source and/or a light source to the microLED devices can function to separate the microLED devices from the sacrificial substrate, without affecting the releasable layer in other areas. Afterward, the sacrificial substrate 1915 can be removed.

In FIG. 19D, a heating process can be applied. For example, the entire substrate, e.g., the substrate with the microLED devices, can be placed in a furnace for annealing. The temperature of the heating process can be slightly higher than the melting of the solderable material. For example, for tin solder material, the heating temperature can be between 350 and 450 C. The molten solder can bridge the connection between the bond pads 1910 and the terminal pads 1921, e.g., forming a solder connection 1951 connecting the bond pads 1910 and the terminal pads 1921. As shown, there can be other solder connections 1952. The positions of the terminal pads and the microLED devices can be determined in advanced, e.g., can be designed, so that the solder layer can bridge the desired connections and not bridging any undesired connections, for example, through the maximum distance that the solder can bridge. The solder bridge can also correct misalignments of the microLED devices, due to the surface tension force.

Upon cooling, excess solder can be removed from the substrate, for example, by air blowing, or by ultrasonic vibration. The substrate can become a microLED display panel or a microLED backplane, e.g., a circuit board having an array of microLED display pixels. The solder layer can perform a simultaneous bridging connection for all the microLED devices, resulting in a massive parallel assembling of the microLED devices on a circuit board.

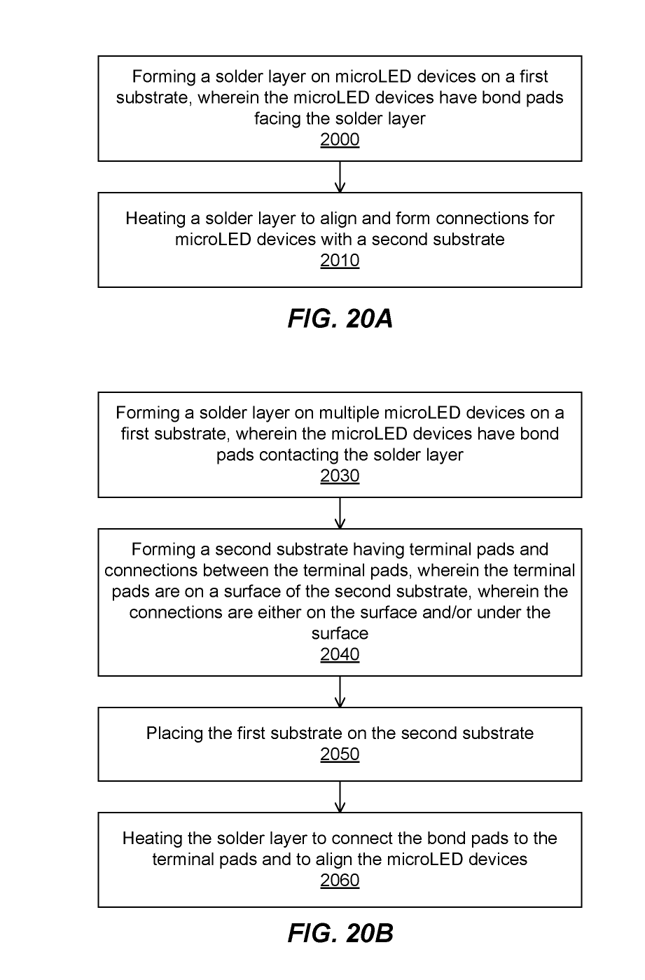

FIGS. 20A-20B illustrate flow charts for forming a microLED display according to some embodiments. In FIG. 20A, operation 2000 forms a solder layer on microLED devices on a first substrate, wherein the microLED devices have bond pads facing the solder layer. Operation 2010 heats a solder layer to align and form connections for microLED devices with a second substrate.

In FIG. 20B, operation 2030 forms a solder layer on multiple microLED devices on a first substrate, wherein the microLED devices have bond pads contacting the solder layer. Operation 2040 forms a second substrate having terminal pads and connections between the terminal pads, wherein the terminal pads are on a surface of the second substrate, wherein the connections are either on the surface and/or under the surface. Operation 2050 places the first substrate on the second substrate. Operation 2060 heats the solder layer to connect the bond pads to the terminal pads and to align the microLED devices.

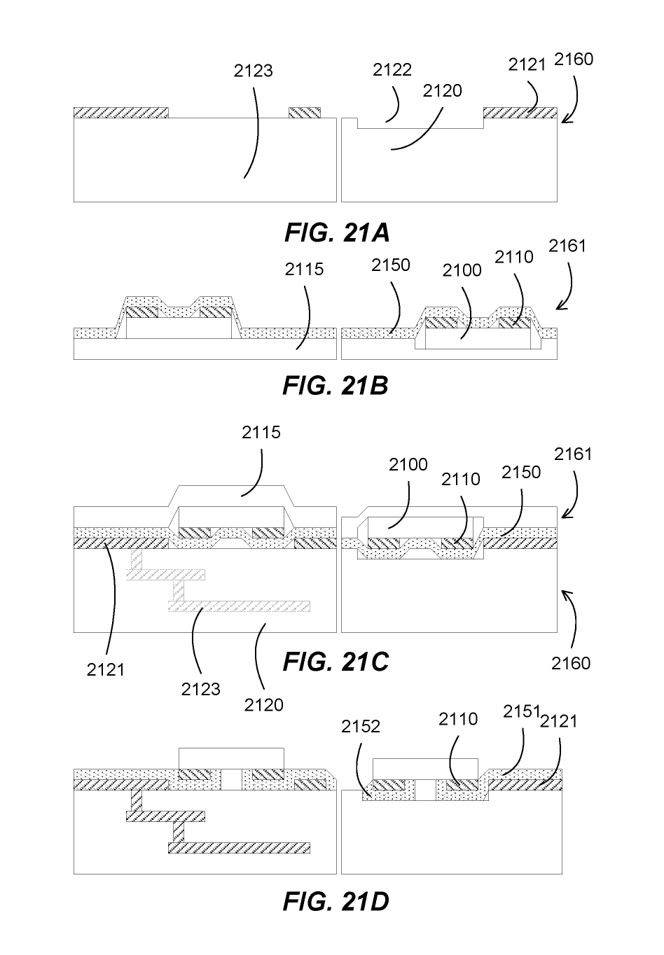

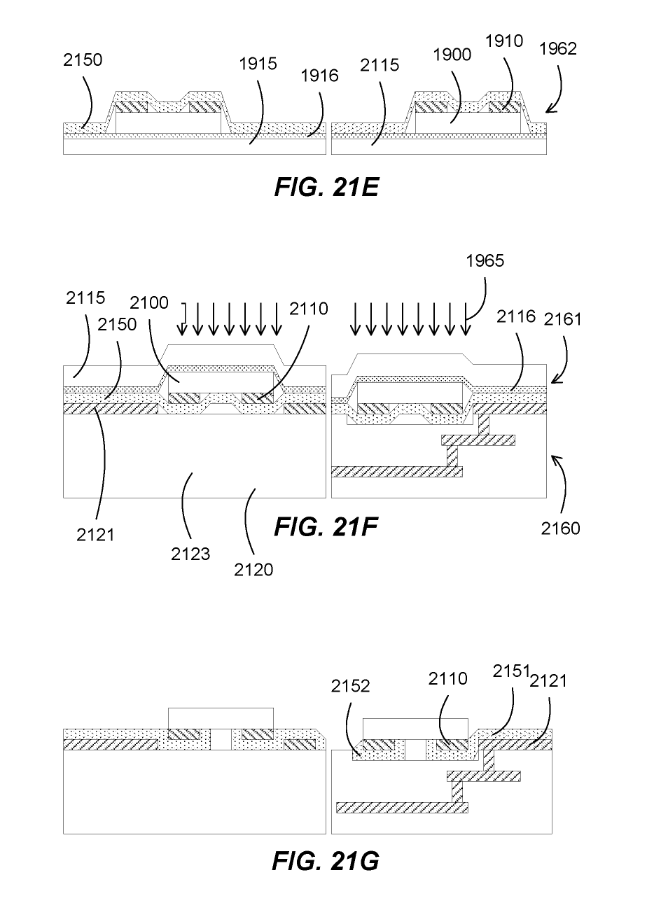

FIGS. 21A-21G illustrate processes for forming a microLED display according to some embodiments. MicroLED devices can be placed on a sacrificial substrate so that the bond pads of the microLED devices are exposed, e.g., not facing the surface of the sacrificial substrate. A solder layer can cover the bond pads, and can be formed on the microLED devices on the sacrificial substrate.

In FIG. 21A, a substrate 2120 can be formed. The substrate can include a circuit board. For example, the substrate can include terminal pads 2121 for coupling with bond pads of microLED devices. The substrate can include interconnects 2123 and optional circuits to drive the microLED devices, e.g., circuits and interconnections necessary for the substrate with the microLED devices to be operable as a microLED display panel. In some embodiments, the substrate can include interconnects and optional circuits necessary for the substrate with the microLED devices to be a component of a microLED display panel, e.g., the substrate can include contact pads for coupling with additional components to form a microLED display panel. For example, the substrate can include a backplane for the display. The substrate can include an insulator material, such as ceramic or glass.

The substrate can include recesses 2122. The recesses can be indentations on the surface of the substrate. The recesses can be about the size of the microLED devices, such as slightly larger to accommodate the microLED devices. In some embodiments, the microLED devices can have shapes that can determine the orientation of the microLED devices when housed in the recesses. For example, the shape of the microLED devices can be rectangular, which can determine a 90 degrees orientation (e.g., perpendicular to each other) due to the also-rectangular recesses. The microLED devices can have a cut corner, which can determine a positive or negative orientation (e.g., facing to the left or to the right) due to the matched-shape recesses.

A first composite substrate 2160 can be formed, including the substrate 2120 with the recesses 2122 and the terminal pads 2121 and the interconnections 2123.

In FIG. 21B, a sacrificial substrate 2115 can be provided. The sacrificial substrate can be a flat substrate. The sacrificial substrate can include recesses or other features, such as protrusions to accommodate the microLED devices.

MicroLED devices 2100 can be placed on the sacrificial substrate 2115. The microLED devices can be placed in the optional recesses or protrusions or can be placed directly on the substrate. The microLED devices can be placed using a pick-and-place process, a thermal adhesion transfer process, a fluidic transfer process, or any other device transfer processes. The microLED devices can be oriented upward, e.g., the back side of the microLED devices, e.g., the surface opposite to the surface of the microLED devices having the bond pads, can contact the sacrificial substrate.

A layer 2150 of a solderable material, such as a tin solder material or a solder material containing tin, can be formed on the sacrificial substrate 2115 and on the microLED devices, e.g., covering the surface areas of the substrate including the bond pads of the microLED devices.

A second composite substrate 2161 can be formed, including the sacrificial substrate 2115 with the optional recesses or protrusions, the microLED devices, and the solder layer 2150.

In FIG. 21C, the second composite substrate 2161 can be placed on the first composite substrate 2160, e.g., the sacrificial substrate 2115 can be placed on the circuit substrate 2120. The composite substrates can be oriented so that the solder layer 2150 can be configured to contact the terminal pads 2121. Thus the terminal pads 2121 and the bond pads 2110 are facing each other with the solder layer in between.

The composite substrates can be further oriented so that the microLED devices can be positioned so that the bond pads are located in a vicinity 2130 of the terminal pads. The distance between the bond pads and the terminal pads can be less than a maximum distance that a solderable material can bridge, e.g., the microLED devices are positioned on the substrate in such a way so that a solder layer can form a connection connecting the bond pads with the terminal pads.

The microLED devices can be positioned so that adjacent microLED devices are farther apart 2140, e.g., not in a same close proximity as the to-be-connected bond pads and terminal pads. In other words, if the microLED devices are not configured to be connected to the terminal pads, the distance between the bond pads of the non-connected microLED devices and the terminal pads can be more than the maximum distance that a solderable material can bridge, e.g., the microLED devices are positioned on the substrate in such a way so that a solder layer cannot form undesired connections between the bond pads of the non-connected microLED devices with the terminal pads.

In FIG. 21D, a heating process can be applied. For example, the entire substrate, e.g., the substrate with the microLED devices, can be placed in a furnace for annealing. The temperature of the heating process can be slightly higher than the melting of the solderable material. For example, for tin solder material, the heating temperature can be between 350 and 450 C. The molten solder can bridge the connection between the bond pads 2110 and the terminal pads 2121, e.g., forming a solder connection 2151 connecting the bond pads 2110 and the terminal pads 2121. As shown, there can be other solder connections 2152. The positions of the terminal pads and the microLED devices can be determined in advanced, e.g., can be designed, so that the solder layer can bridge the desired connections and not bridging any undesired connections, for example, through the maximum distance that the solder can bridge. The solder bridge can also correct misalignments of the microLED devices, due to the surface tension force.

Upon cooling, excess solder can be removed from the substrate, for example, by air blowing, or by ultrasonic vibration. The substrate can become a microLED display panel or a microLED backplane, e.g., a circuit board having an array of microLED display pixels. The solder layer can perform a simultaneous bridging connection for all the microLED devices, resulting in a massive parallel assembling of the microLED devices on a circuit board.

The sacrificial substrate 2115 can be removed.

FIGS. 21E-21G show another process for forming the microLED display.

In FIG. 21E, a third composite substrate 2162 can be formed, instead of the second composite substrate 2161. In the third composite substrate 2162, a releasable layer 2116 can be disposed between the microLED devices 2100 and the sacrificial substrate 2115, e.g., the third composite substrate can include the microLED devices disposed on the releasable layer on the sacrificial substrate. The releasable layer can include a releasable material as disclosed above. Alternatively, the reliable layer can be omitted if the sacrificial substrate can function as a releasable layer, e.g., the sacrificial substrate can be etched or dissolved to be separated from the microLED devices.

A third composite substrate 2162 can be formed, including the sacrificial substrate 2115 with the optional recesses or protrusions, the releasable layer, the microLED devices, and the solder layer 2150.

In FIG. 21F, the third composite substrate 2162 can be placed on the first composite substrate 2160, e.g., the sacrificial substrate 2115 can be placed on the circuit substrate 2120. The composite substrates can be oriented so that the solder layer 2150 can be configured to contact the terminal pads 2121. Thus the terminal pads 2121 and the bond pads 2110 are facing each other with the solder layer in between.

A releasable process can be performed to release the microLED devices from the sacrificial substrate. For example, a blanket exposure of the sacrificial substrate of a heat source and/or a light source can dissolve the releasable layer, separating the microLED devices from the sacrificial substrate. Alternatively, a selected application 2165 of a heat source and/or a light source to the microLED devices can function to separate the microLED devices from the sacrificial substrate, without affecting the releasable layer in other areas. Afterward, the sacrificial substrate 2115 can be removed.

In FIG. 21G, a heating process can be applied. For example, the entire substrate, e.g., the substrate with the microLED devices, can be placed in a furnace for annealing. The molten solder can bridge the connection between the bond pads and the terminal pads. The solder bridge can also correct misalignments of the microLED devices, due to the surface tension force.

Upon cooling, excess solder can be removed from the substrate.

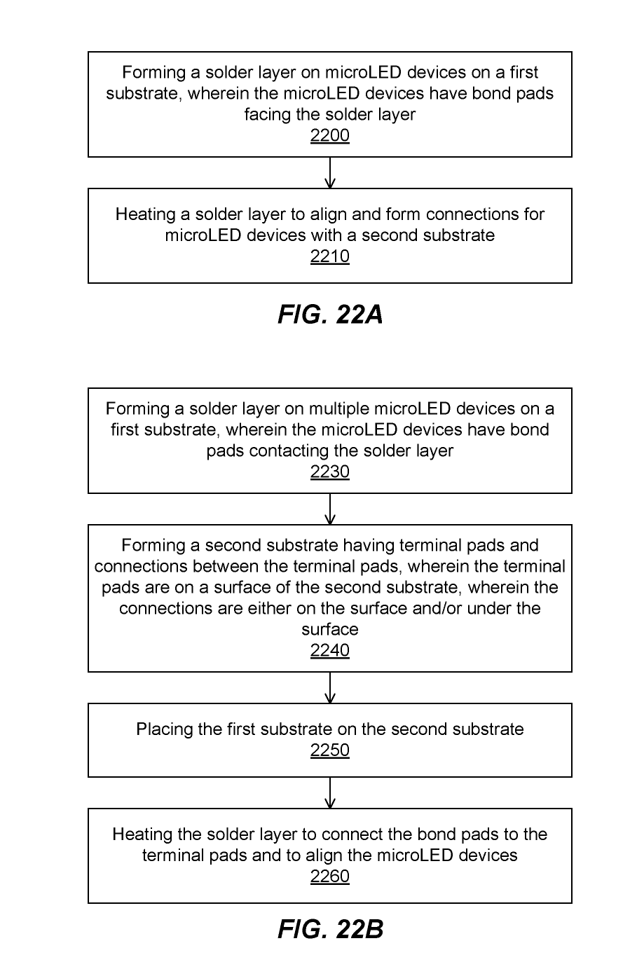

FIGS. 22A-22B illustrate flow charts for forming a microLED display according to some embodiments. In FIG. 22A, operation 2200 forms a solder layer on microLED devices on a first substrate, wherein the microLED devices have bond pads facing the solder layer. Operation 2210 heats a solder layer to align and form connections for microLED devices with a second substrate.

In FIG. 22B, operation 2230 forms a solder layer on multiple microLED devices on a first substrate, wherein the microLED devices have bond pads contacting the solder layer. Operation 2240 forms a second substrate having terminal pads and connections between the terminal pads, wherein the terminal pads are on a surface of the second substrate, wherein the connections are either on the surface and/or under the surface. Operation 2250 places the first substrate on the second substrate. Operation 2260 heats the solder layer to connect the bond pads to the terminal pads and to align the microLED devices.

In some embodiments, the microLED devices can be transferred from the as-fabricated wafer to the circuit substrate or to the sacrificial substrate. A lithography process can be used, so that the array on the temporary substrate can be a perfect match with the target array on the permanent substrate. When the array on the temporary substrate is made using this identical lithography, the XY locations of the contact pads across the whole array are preserved, even in the diced chips, and these XY locations can be easily restored in an assembly of multiple chips, as many chips as are required. Once attached to the permanent substrate with self-aligned tin solder, the temporary substrate can be quickly removed to re-create the original large array on the permanent substrate.

In some embodiments, the transfer of the microLED devices can be performed through a mask. For example, a mask, such as a polyimide mask, can be placed on the substrate. The mask can have holes that correspond to the location of the microLED devices. The holes can be formed by a laser, e.g., using a laser ablation process. The microLED devices can be dropped in the substrate through the mask.

In some embodiments, the shape of the holes can be formed so that the microLED devices can have the desired orientation, e.g., the bond pads of the microLED devices are disposed in a vicinity of the corresponded terminal pads.

In some embodiments, the polyimide mask can be coated with a layer of solder. When the microLED devices is dropped to the holes of the polyimide mask, the microLED devices can be pressed into the soft solder layer, which can provide adhesion so that the microLED devices can stick to the solder layer.

In some embodiments, a sacrificial substrate or a temporary substrate can include a thin substrate of a paper or a polymer material such as a plastic sheet. A solder layer can be deposited on the paper or plastic sheet. The polyimide mask having laser holes can be placed on the solder layer. MicroLED devices can be placed in the holes of the polyimide mask, and pressed into the solder layer. The polyimide mask can be removed, leaving the microLED devices on the solder layer on the paper or plastic sheet. The substrate with the paper or plastic sheet having microLED devices adhere to a solder layer can be used as a decal carrier for transferring the microLED devices.

The microLED devices, after fabricated and diced and optionally assembled into subassemblies, can be picked up and transferred to a receiving substrate. A transfer head can be positioned over the carrier substrate having an array of microLED devices disposed thereon, and an operation is performed to create a phase change in the bonding layer for at least one of the microLED devices. For example, the operation may be heating the bonding layer above a liquidus temperature or melting temperature of the bonding layer, or altering a crystal phase of the bonding layer.

Then at least one microLED device including the micro p-n diode and the metallization layer, and optionally a portion of the bonding layer for the at least one of the micro LED structures may be picked up with a transfer head and placed on a receiving substrate.

If a conformal dielectric barrier layer has already been formed, a portion of the conformal dielectric barrier layer may also be picked up with the micro p-n diode and the metallization layer. Alternatively, a conformal dielectric barrier layer can be formed over the microLED device, or plurality of microLED devices, after being placed on the receiving substrate.

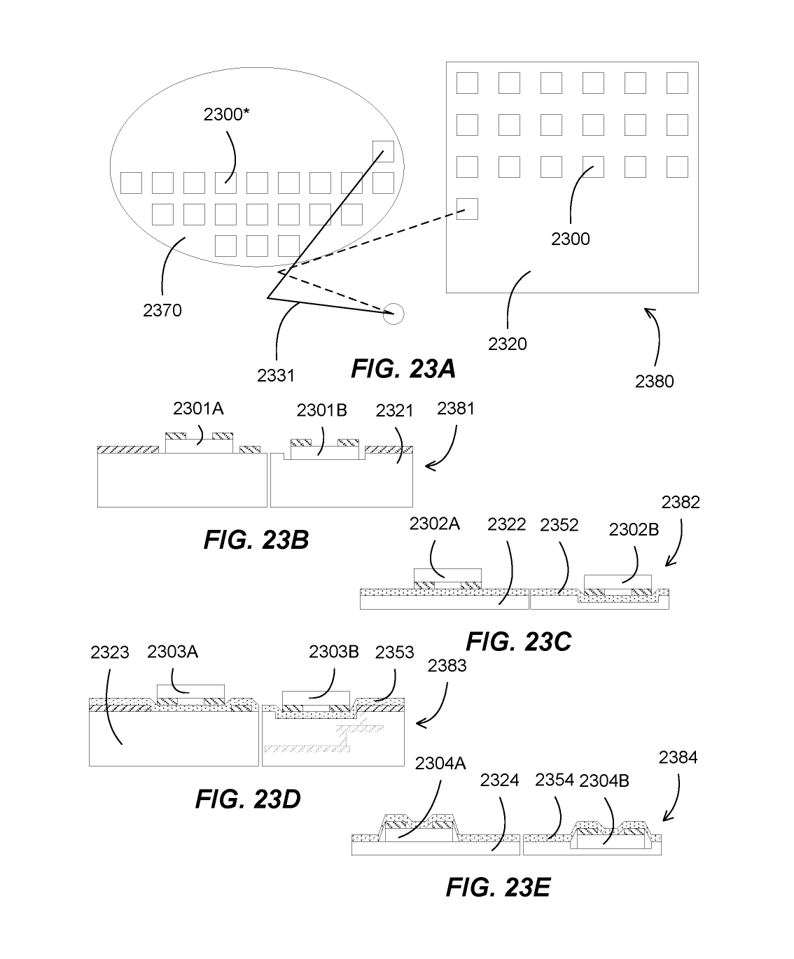

FIGS. 23A-23E illustrate a pick-and-place process for forming microLED display according to some embodiments. In FIG. 23A, a pick and place robot 2331 can be used to pick microLED devices 2300* from a location 2370 to be placed as microLED devices 2300 on a substrate 2320. A substrate 2380, such as a circuit substrate or a temporary substrate or a sacrificial substrate, can include a substrate 2320 and the microLED devices, together with other components such as terminal pads, interconnects, solder layer, and releasable layer. The substrate 2380 can be used in the fabrication process to form microLED displays or panels as discussed above.

FIGS. 23B-23E show different substrates using the assembled microLED devices. In FIG. 23B, a substrate 2381 can include a circuit substrate 2321, e.g., a circuit board or a substrate having terminal pads and interconnects, together with the microLED devices 2301A and 2301B assembled thereon. In FIG. 23C, a substrate 2382 can include a temporary or sacrificial substrate 2322, e.g., a substrate coated with a releasable layer or a substrate that can be removed or dissolved by etching, a solder layer 2352 on the substrate, together with the microLED devices 2302A and 2302B assembled on the solder layer.

In FIG. 23D, a substrate 2383 can include a circuit substrate 2321, e.g., a circuit board or a substrate having terminal pads and interconnects, a solder layer 2353 on the substrate, and the microLED devices 2303A and 2303B assembled on the solder layer. In FIG. 23E, a substrate 2384 can include a temporary or sacrificial substrate 2324, e.g., a substrate coated with a releasable layer or a substrate that can be removed or dissolved by etching, the microLED devices 2302A and 2302B assembled on the substrate, and a solder layer 2354 on the microLED devices and on the exposed areas of the substrate.

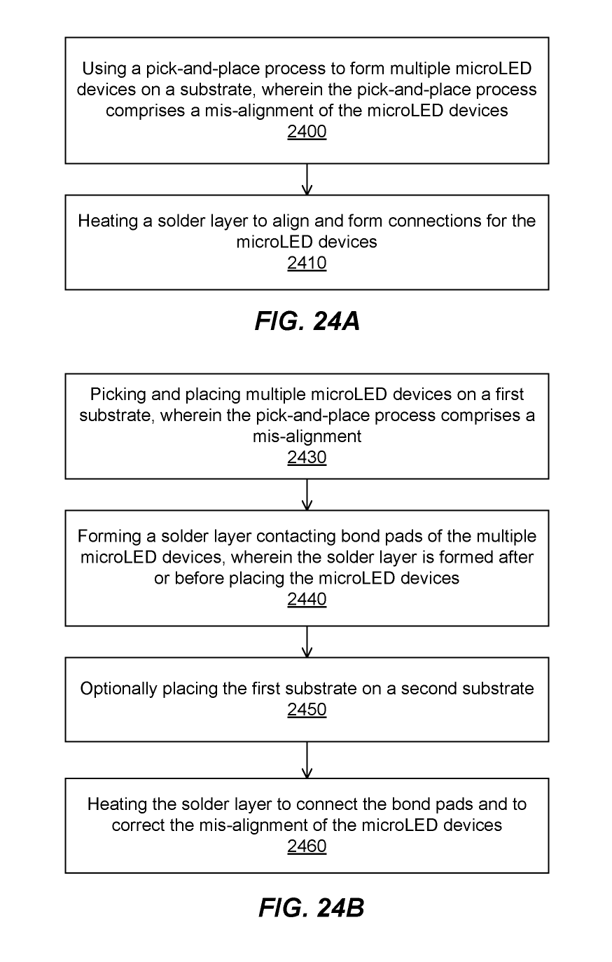

FIGS. 24A-24B illustrate flow charts for forming microLED displays using a pick-and-place process according to some embodiments. In FIG. 24A, operation 2400 uses a pick-and-place process to form multiple microLED devices on a substrate, wherein the pick-and-place process comprises a misalignment of the microLED devices. Operation 2410 heats a solder layer to align and form connections for the microLED devices.

In FIG. 24B, operation 2430 picks and places multiple microLED devices on a first substrate, wherein the pick-and-place process comprises a misalignment. Operation 2440 forms a solder layer contacting bond pads of the multiple microLED devices, wherein the solder layer is formed after or before placing the microLED devices. Operation 2450 optionally places the first substrate on a second substrate. Operation 2460 heats the solder layer to connect the bond pads and to correct the misalignment of the microLED devices.

In some embodiments, the microLED devices can be assembled on a substrate through a releasable transfer process. A releasable transfer process can include adhering objects on a releasable layer on a donor substrate. Upon moving the donor substrate to a receiving substrate, the releasable can be released, e.g., removing the adhesion between the objects and the donor substrate and pacing the objects on the receiving substrate. The objects can all be released together, or individual objects can be selectively released, depending on either a blanket application of energy or a selective application of energy.

The releasing action of the releasable layer can be accomplished by supplying energy to the releasable layer, such as by an application of heat and/or light. For example, a polymer can sublime upon the application of heat and light, as disclosed in U.S. Pat. Nos. 6,946,178 and 7,141,348, hereby incorporated by reference in their entirety. Other releasable materials can be used.

The releasable transfer process can provide a simultaneous transfer of multiple devices, thus can provide a high throughput transfer process. The releasable transfer process can provide a selective transfer of selected devices, thus can provide a flexible transfer process.

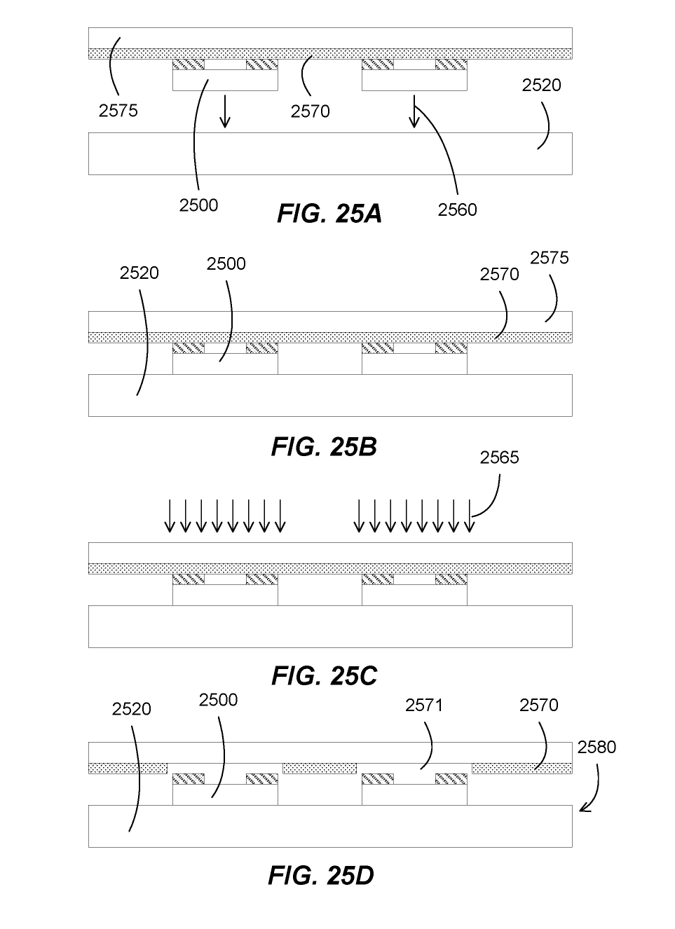

FIGS. 25A-25D illustrate a releasable transfer process for forming microLED display according to some embodiments. In FIG. 25A, a donor substrate can include microLED devices 2500 adhering to a releasable layer 2570 on a temporary substrate 2575. The donor substrate can be brought 2560 in proximity, or contacting, with a receiving substrate 2520, such as a circuit substrate or a circuit board having terminal pads and interconnects designed for a microLED display or panel.

In FIG. 25B, the donor substrate is in contact with the receiving substrate. Alternatively, the donor substrate can be close, but not touching, the receiving substrate.

In FIG. 25C, an application of energy 2565 can be used to release the microLED devices, for example, by removing or dissolving the releasable layer, or in general, by removing the adhesion between the microLED devices and the donor substrate. The energy can include a thermal energy, e.g., by heating, or a photon energy, e.g., by lighting with a laser or other light source such as focused light.

The releasing of the microLED devices can be preformed simultaneously, e.g., multiple microLED devices can be released together from the donor substrate to the receiving substrate. If the microLED devices are already disposed in correct positions as a pixel array on the donor substrate, the releasable transfer can be performed in parallel, as to transfer multiple microLED devices in one application of energy.

The releasing of the microLED devices can be preformed selectively, e.g., one or more microLED devices can be released from the donor substrate to the receiving substrate. For example, the microLED devices can be adhered to a tape after being fabricated in a wafer. The microLED devices on the wafer are diced (but still adhered to a tape). A releasable layer can be coated to the tape before adhering to the microLED wafer, making the tape, after dicing the microLED devices, becoming a donor substrate. Individual microLED devices can be releasable transferred to the receiving substrate, through the selective application of energy, e.g., applying energy to the microLED devices that are needed to be released to the receiving substrate. The donor substrate then can move to a new location to release other microLED devices.

In FIG. 25D, the donor substrate can be removed, after the microLED devices have been transferred. The receiving substrate can become a substrate 2580 with an array of microLED devices disposed thereon.

The releasable transfer process can be applied to form a substrate in the process of assembling a microLED display or panel, as discussed above in FIGS. 12-22, and in FIGS. 23B-23E with respect to the pick and place transfer.

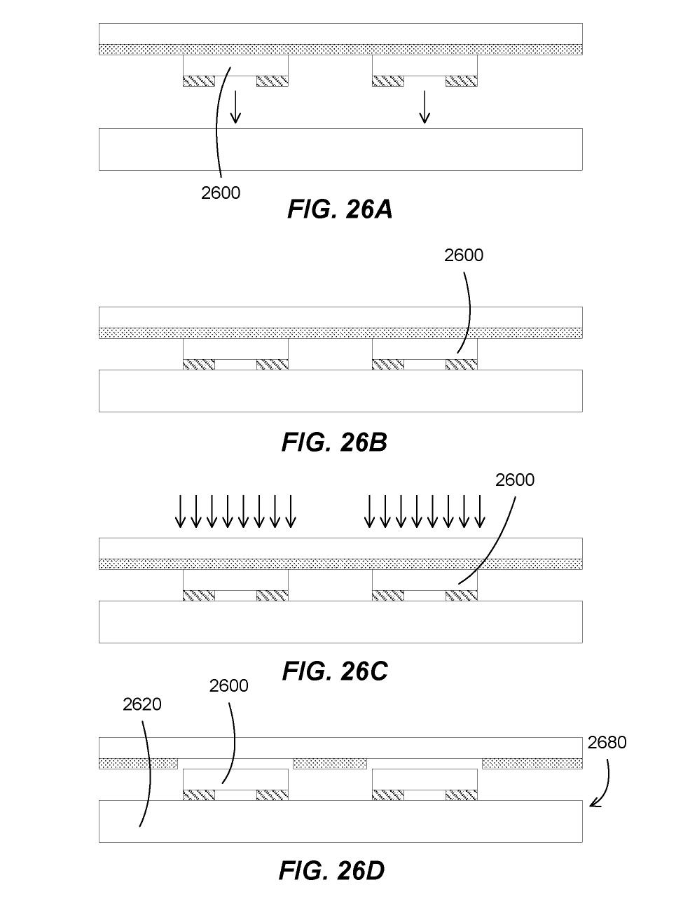

FIGS. 26A-26D illustrate a releasable transfer process for forming microLED display according to some embodiments. The releasable transfer process is similar to the process described above, but with a different orientation of the microLED devices 2600. The microLED devices 2500 can be oriented upward on the receiving substrate 2520, e.g., the bond pads of the microLED devices face away from the receiving substrate and exposed to the ambient, e.g., the back side of the microLED devices (the surface of the microLED devices that is opposite to the surface having the bond pads) is on contact with the surface of the receiving substrate. To accomplish this orientation, the microLED devices can be disposed in an opposite orientation in the donor substrate.

The microLED devices 2600 can be oriented downward on the receiving substrate 2620, e.g., the bond pads of the microLED devices face the receiving substrate, e.g., the surface of the microLED devices having the bond pads is on contact with the surface of the receiving substrate. To accomplish this orientation, the microLED devices can be disposed in an opposite orientation in the donor substrate.

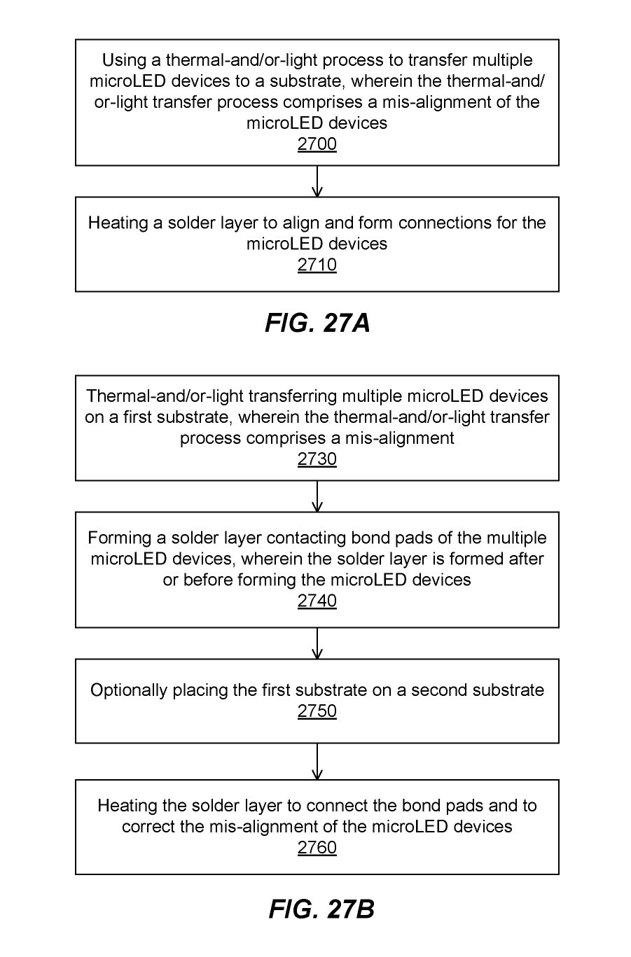

FIGS. 27A-27B illustrate flow charts for forming microLED displays using a releasable transfer process according to some embodiments. In FIG. 27A, operation 2700 uses a thermal-and/or-light process to transfer multiple microLED devices to a substrate, wherein the thermal-and/or-light transfer process comprises a misalignment of the microLED devices. Operation 2710 heats a solder layer to align and form connections for the microLED devices.

In FIG. 27B, operation 2730 thermal-and/or-light transfers multiple microLED devices on a first substrate, wherein the thermal-and/or-light transfer process comprises a misalignment. Operation 2740 forms a solder layer contacting bond pads of the multiple microLED devices, wherein the solder layer is formed after or before forming the microLED devices. Operation 2750 optionally places the first substrate on a second substrate. Operation 2760 heats the solder layer to connect the bond pads and to correct the misalignment of the microLED devices.

In some embodiments, the microLED devices can be assembled on a substrate through a fluidic transfer process. The microLED devices can be disposed in a fluid, e.g., the microLED devices can float in a fluid. A thin layer of the fluid containing the microLED devices can be disposed on a receiving substrate. The receiving substrate can be recesses or holes that having similar size and shape of the microLED devices to receive the microLED devices. The recesses can be formed directly on the receiving substrate. The receiving substrate can be coated with a layer, such as a polyimide layer. And the recesses can be formed by a laser ablation process, cutting through holes through the polyimide layer and stopped at the receiving substrate.

When the fluid is drained, the microLED devices can stay on the receiving substrate, e.g., staying in the recesses or holes on the surface of the receiving substrate.

The lateral orientation of the microLED devices can be achieved by the shape of the recesses, for example, by performing a laser cut process to achieve the desired shape.

The vertical orientation of the microLED devices, e.g., the upward or downward placing of the microLED devices (the bond pads are facing upward, e.g., exposed to the ambient, or facing downward, e.g., contacting the surface of the receiving substrate), can be achieved by magnetic alignment. For example, a magnetic field can be established in the receiving substrate. The bond pads of the microLED devices can be fabricated with a magnetic material, e.g., a material having a magnetic property such as nickel. The bond pads can respond to the applied magnetic filed to align the microLED devices in an upward or downward orientation as designed.

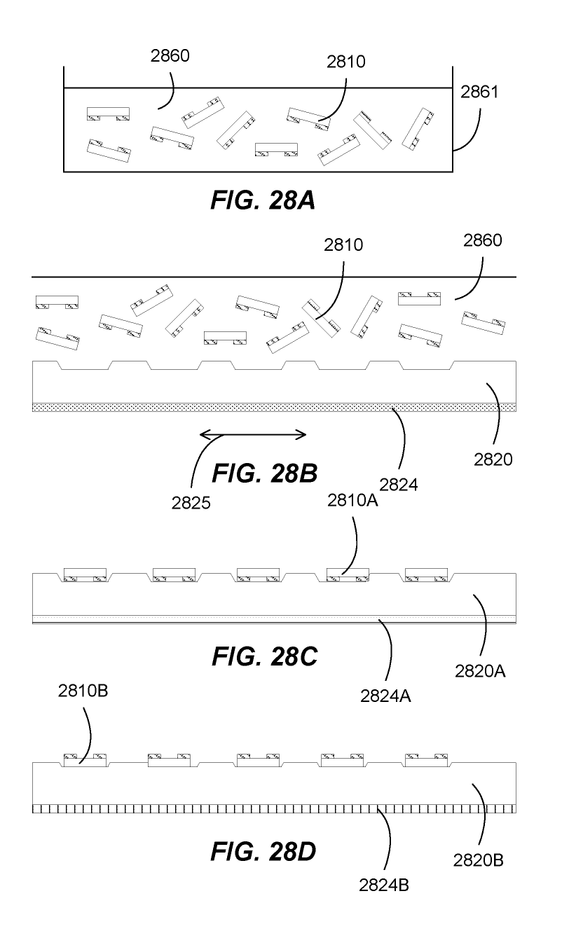

FIGS. 28A-28D illustrate a fluidic transfer process for forming microLED display according to some embodiments. In FIG. 28A, a fluid 2860 can be prepared having microLED devices floated therein. The fluid 2860 can be disposed in a container 2861.

In FIG. 28B, the fluid 2860 can be disposed as a thin layer of fluid on a receiving substrate 2820. The receiving substrate can have recesses corresponded to the size and shape and orientation of the microLED devices. A vibration mechanism 2825 can be included to shake the receiving substrate to reduce misalignments of the microLED devices in the recesses. In contrast to the prior art fluidic assembling process, the present methods can correct the misalignments of the microLED devices, and thus the fluidic transfer process can be simpler and more robust with minor misalignments correctable in the subsequent process of soldering.

An alignment mechanism 2824 can be included to align the up/down orientation of the microLED devices. The alignment mechanism can include a magnetic field with appropriate direction and magnitude to turn the microLED devices into proper orientation.

In FIGS. 28C-28D, the fluid is drained, leaving the microLED devices in the recesses, with proper lateral and up/down orientations. Minor misalignments can be corrected in the subsequent soldering process as disclosed above. In FIG. 28C, the microLED devices 2810A can be disposed in a downward orientation (the bond pads contacting the surface of the receiving substrate) in the recesses of the receiving substrate 2820A, using the magnetic field 2824A. In FIG. 28D, the microLED devices 2810B can be disposed in an upward orientation (the bond pads facing away from the surface of the receiving substrate) in the recesses of the receiving substrate 2820B, using the magnetic field 2824B.

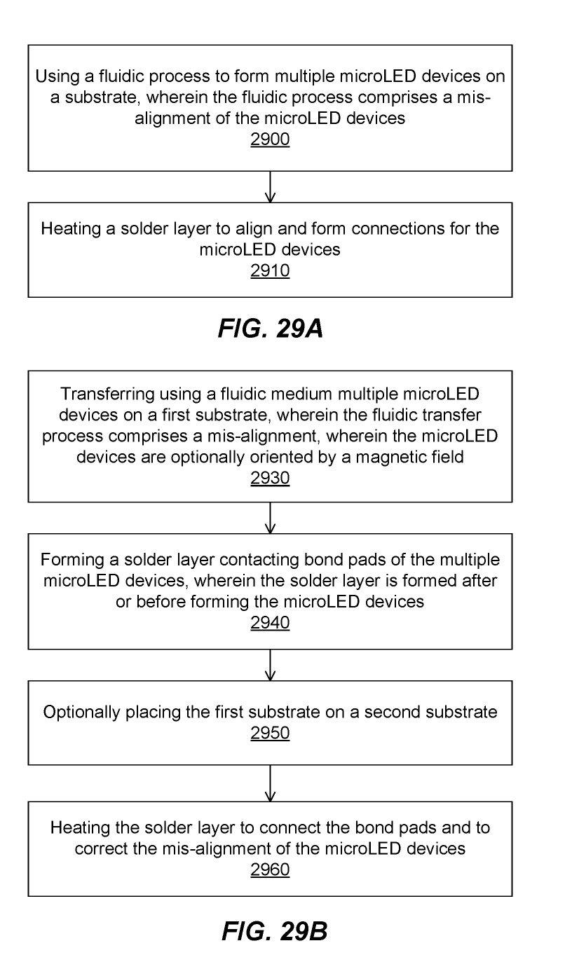

FIGS. 29A-29B illustrate flow charts for forming microLED displays using a fluidic transfer process according to some embodiments. In FIG. 29A, operation 2900 uses a fluidic process to form multiple microLED devices on a substrate, wherein the fluidic process comprises a misalignment of the microLED devices. Operation 2910 heats a solder layer to align and form connections for the microLED devices.

In FIG. 29B, operation 2930 transfers using a fluidic medium multiple microLED devices on a first substrate, wherein the fluidic transfer process comprises a misalignment, wherein the microLED devices are optionally oriented by a magnetic field. Operation 2940 forms a solder layer contacting bond pads of the multiple microLED devices, wherein the solder layer is formed after or before forming the microLED devices. Operation 2950 optionally places the first substrate on a second substrate. Operation 2960 heats the solder layer to connect the bond pads and to correct the misalignment of the microLED devices.

What is claimed is:

1. A method to form a microLED display, the method comprising
forming a substrate,
wherein the substrate comprises terminal pads disposed on a surface of the substrate,
wherein the substrate comprises interconnections under the surface,
wherein the interconnections are coupled to the terminal pads to form a connection network for the microLED display;
forming a layer of solder and multiple microLED devices on the substrate,
wherein the multiple microLED devices comprise bond pads,
wherein the layer of solder is configured to contact the bond pads,
wherein the multiple microLED devices are disposed on the substrate so that the bond pads are in a vicinity of the terminal pads;
heating the layer of solder,
wherein the heating is configured so that portions of the layer of solder form connections at least between a bond pad of the bond pads to a terminal pad of the terminal pads,
wherein the heating is configured to correct misalignments of the multiple microLED devices due to the forming of the multiple microLED devices on the substrate so that the multiple microLED devices are in positions for forming the microLED display.

2. A method as in claim 1 wherein the interconnections are further disposed on the surface.

3. A method as in claim 1
wherein the layer of solder is disposed on the substrate,
wherein the multiple microLED devices are disposed on the layer of solder with the bond pads contacting the layer of solder.

4. A method as in claim 1
wherein the multiple microLED devices are disposed on the substrate,
wherein the layer of solder is disposed on the multiple microLED devices on the substrate,
wherein the multiple microLED devices are disposed so that the bond pads contact the layer of solder.

5. A method as in claim 1
wherein the substrate comprises recesses for housing the multiple microLED devices,
wherein the multiple microLED devices are formed in the recesses with the misalignments.

6. A method as in claim 1 wherein the multiple microLED devices are formed on the substrate with the misalignments.

7. A method as in claim 1 further comprising
removing portions of the layer of solder not forming the connections.

8. A method as in claim 1 wherein the multiple microLED devices are formed on the substrate by a pick and place process.

9. A method as in claim 1 wherein the multiple microLED devices are formed on the substrate by a transfer process using at least one of a thermal energy and a light beam.

10. A method as in claim 1 wherein the multiple microLED devices are formed on the substrate by a fluidic transfer process.

11. A method to form a microLED display, the method comprising
forming a first substrate,
wherein the first substrate comprises a layer of solder and multiple microLED devices on the first substrate,
wherein the multiple microLED devices comprise bond pads,
wherein the layer of solder is configured to contact the bond pads;
forming a second substrate,
wherein the second substrate comprises terminal pads disposed on a surface of the second substrate,
wherein the second substrate comprises interconnections under the surface,
wherein the interconnections are coupled to the terminal pads to form a connection network for the microLED display;
placing the first substrate on the second substrate,
wherein the first and second substrates are positioned so that the bond pads are in a vicinity of the terminal pads;
heating the layer of solder,
wherein the heating is configured to connect a bond pad of the bond pads to a terminal pad of the terminal pads,
wherein the heating is configured to correct misalignments of the multiple microLED devices due to the forming of the multiple microLED devices on the substrate so that the multiple microLED devices are in positions for forming the microLED display.

12. A method as in claim 11
wherein the layer of solder is disposed on the first substrate,
wherein the multiple microLED devices are disposed on the layer of solder with the bond pads contacting the layer of solder.

13. A method as in claim 11
wherein the multiple microLED devices are disposed on the first substrate,
wherein the layer of solder is disposed on the multiple microLED devices on the first substrate,
wherein the multiple microLED devices are disposed so that the bond pads contact the layer of solder.

14. A method as in claim 11 wherein the multiple microLED devices are formed on the first substrate with the misalignments.

15. A method as in claim 11 wherein the multiple microLED devices are formed on the second substrate with the misalignments due to the placing of the first substrate on the second substrate.

16. A method as in claim 11 further comprising
removing portions of the layer of solder not forming the connections.

17. A method as in claim 11 further comprising
removing the multiple microLED devices that are bonded to the terminal pads from the first substrate.

18. A method to form a microLED display, the method comprising
forming a first substrate,
wherein the first substrate comprises multiple microLED devices,
wherein the multiple microLED devices comprise bond pads;
forming a second substrate,
wherein the second substrate comprises terminal pads disposed on a surface of the second substrate,
wherein the second substrate comprises interconnections under the surface,
wherein the interconnections are coupled to the terminal pads to form a connection network for the microLED display;
forming a layer of solder on the second substrate;
placing the first substrate on the second substrate,
wherein the layer of solder is configured to contact the bond pads,
wherein the first and second substrates are positioned so that the bond pads are in a vicinity of the terminal pads;
heating the layer of solder,
wherein the heating is configured to connect a bond pad of the bond pads to a terminal pad of the terminal pads,
wherein the heating is configured to correct misalignments of the multiple microLED devices due to the forming of the multiple microLED devices on the substrate so that the multiple microLED devices are in positions for forming the microLED display.

19. A method as in claim 18 further comprising
forming a sacrificial layer on the first substrate and under the multiple microLED devices, wherein the sacrificial layer is configured to release the multiple microLED devices under an application of at least one of a thermal energy and a light beam.

20. A method as in claim 18 further comprising
releasing the multiple microLED devices from the first substrate after placing the first substrate on the second substrate,
removing the first substrate from the second substrate after releasing the multiple microLED devices.
